(19) United States
(12) Patent Application Publication
(10) Pub. No.: US 2025/0366125 A1
(43) Pub. Date: Nov. 27, 2025

(54) STRUCTURE AND FORMATION METHOD OF SEMICONDUCTOR DEVICE WITH EPITAXIAL STRUCTURE

(71) Applicant: Taiwan Semiconductor Manufacturing Company, Ltd., Hsinchu (TW)

(72) Inventor: Ka-Hing FUNG, Zhudong Township (TW)

(73) Assignee: Taiwan Semiconductor Manufacturing Company, Ltd., Hsinchu (TW)

(21) Appl. No.: 18/883,869

(22) Filed: Sep. 12, 2024

Related U.S. Application Data
(60) Provisional application No. 63/651,639, filed on May 24, 2024.

(51) Int. Cl. H01L 29/66; H01L 23/00; H01L 27/088; H01L 29/06; H01L 29/417; H01L 29/423; H01L 29/775; H01L 29/786

(52) U.S. Cl. CPC H10D 64/018; H10D 30/014; H10D 30/43; H10D 30/6735; H10D 30/6757; H10D 62/121; H10D 64/258; H10D 84/83; H01L 24/08; H01L 2224/08145

(57) ABSTRACT

A semiconductor device structure and a formation method are provided. The method includes forming multiple semiconductor nanostructures and multiple dielectric nanostructures over a substrate. The semiconductor nanostructures and the dielectric nanostructures are laid out in an alternating manner. The method also includes forming inner spacers over edges of the dielectric nanostructures and forming a continuous semiconductor layer along edges of the semiconductor nanostructures and the inner spacers. The method further includes annealing the continuous semiconductor layer to form a crystallized semiconductor layer and growing an epitaxial structure on the crystallized semiconductor layer.

This Application claims the benefit of U.S. Provisional Application No. 63/651,639, filed on May 24, 2024, the entirety of which is incorporated by reference herein.

### BACKGROUND

The semiconductor integrated circuit (IC) industry has experienced rapid growth. Technological advances in IC materials and design have produced generations of ICs. Each generation has smaller and more complex circuits than the previous generation.

Over the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1B are top views of various stages of a process for forming a portion of a semiconductor device structure, in accordance with some embodiments.

FIGS. 2A-2D are cross-sectional views of various stages of a process for forming a portion of a semiconductor device structure, in accordance with some embodiments.

FIGS. 3A-3O are cross-sectional views of various stages of a process for forming portions of a semiconductor device structure, in accordance with some embodiments.

FIG. 4 is a cross-sectional view of an intermediate stage of a process for forming portions of a semiconductor device structure, in accordance with some embodiments.

FIGS. 5A-5G are cross-sectional views of various stages of a process for forming portions of a semiconductor device structure, in accordance with some embodiments.

FIGS. 6A-6G are cross-sectional views of various stages of a process for forming portions of a semiconductor device structure, in accordance with some embodiments.

FIGS. 7A-7C are cross-sectional views of various stages of a process for forming portions of a semiconductor device structure, in accordance with some embodiments.

FIG. 8A is a cross-sectional view of a portion of a semiconductor device structure, in accordance with some embodiments.

FIG. 8B is a cross-sectional view of a portion of a semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher, such as 95% or higher, especially 99% or higher, including 100% of what is specified. Furthermore, terms such as “substantially parallel” or “substantially perpendicular” are to be interpreted as not to exclude insignificant deviation from the specified arrangement and may include for example deviations of up to 10 degrees in some embodiments. The word “substantially” does not exclude “completely” e.g. a composition which is “substantially free” from Y may be completely free from Y in some embodiments.

Terms such as “about” in conjunction with a specific distance or size are to be interpreted so as not to exclude insignificant deviation from the specified distance or size and may include for example deviations of up to 10% of what is specified in some embodiments. The term “about” in relation to a numerical value x may mean x ±5 or 10% of what is specified in some embodiments.

Embodiments of the disclosure may relate to FinFET structure having fins. The fins may be patterned using any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. However, the fins may be formed using one or more other applicable processes.

Embodiments of the disclosure may relate to the gate all around (GAA) transistor structures. The GAA structure may be patterned using any suitable method. For example, the structures may be patterned using one or more photolithography processes, including double-patterning or multi-patterning processes. In some embodiments, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

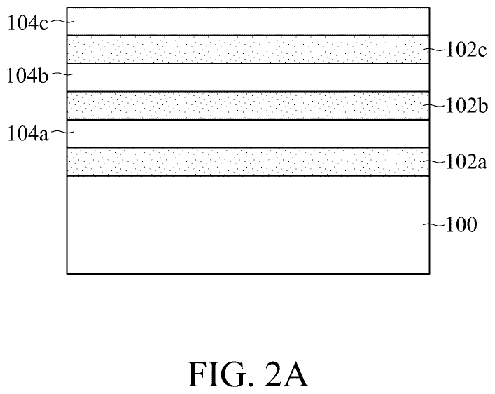

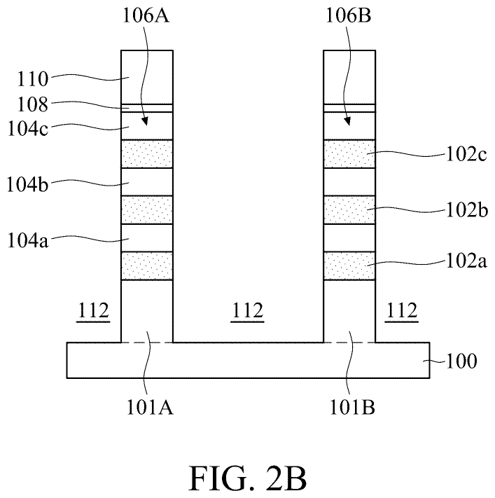

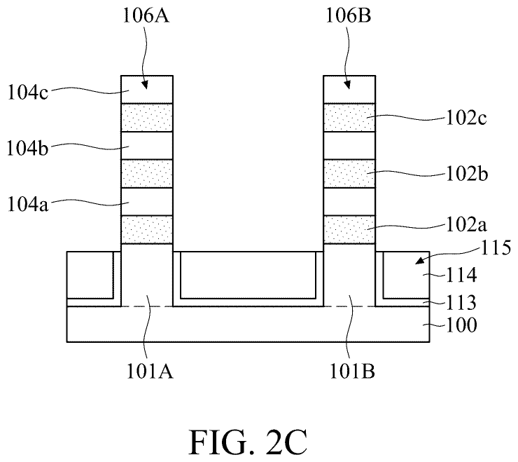

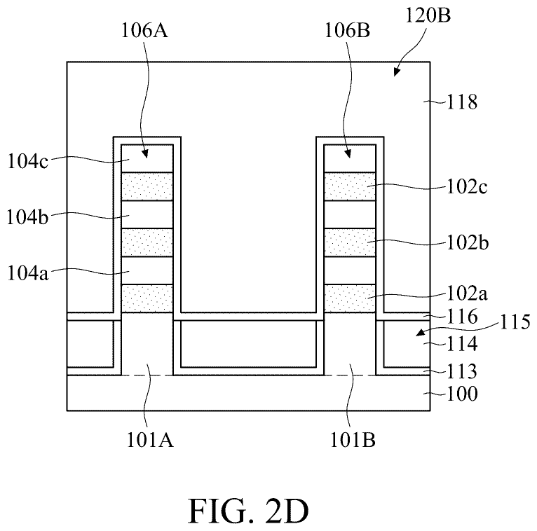

FIGS. 2A-2D are cross-sectional views of various stages of a process for forming a portion of a semiconductor device structure, in accordance with some embodiments. As shown in FIG. 2A, a semiconductor substrate 100 is received or provided. In some embodiments, the semiconductor substrate 100 is a bulk semiconductor substrate, such as a semiconductor wafer. The semiconductor substrate 100 may include silicon or other elementary semiconductor materials such as germanium. The semiconductor substrate 100 may be un-doped or doped (e.g., p-type, n-type, or a combination thereof). In some embodiments, the semiconductor substrate 100 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 100 includes a compound semiconductor. For example, the compound semiconductor includes one or more III-V compound semiconductors having a composition defined by the formula Al_{X1}Ga_{X2}In_{X3}A_{SY1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate 100 includes a silicon-germanium layer formed on a bulk silicon layer.

As shown in FIG. 2A, a semiconductor stack having multiple semiconductor layers is formed over the semiconductor substrate 100, in accordance with some embodiments. In some embodiments, the semiconductor stack includes multiple semiconductor layers 102a, 102b, and 102c. The semiconductor stack also includes multiple semiconductor layers 104a, 104b, and 104c. In some embodiments, the semiconductor layers 102a-102c and the semiconductor layers 104a-104c are laid out in an alternating manner, as shown in FIG. 2A.

In some embodiments, the semiconductor layers 102a-102c function as sacrificial layers that will be removed in a subsequent process to release the semiconductor layers 104a-104c. The semiconductor layers 104a-104c that are released form multiple semiconductor nanostructures. The semiconductor layers 104a-104c may function as the channel structures of one or more transistors.

In some embodiments, the semiconductor layers 104a-104c that will be used to form channel structures are made of a material that is different than that of the semiconductor layers 102a-102c. In some embodiments, the semiconductor layers 104a-104c are made of or include silicon, germanium, other suitable materials, or a combination thereof. In some embodiments, the semiconductor layers 102a-102c are made of or include silicon germanium. In some other embodiments, the semiconductor layers 104a-104c are made of silicon germanium, and the semiconductor layers 102a-102c are made of silicon germanium with different atomic concentration of germanium than that of the semiconductor layers 104a-104c. Due to the different compositions, different etching selectivity and/or different oxidation rates during subsequent processing may be achieved between the semiconductor layers 102a-102c and the semiconductor layers 104a-104c.

The present disclosure contemplates that the semiconductor layers 102a-102c and the semiconductor layers 104a-104c include any combination of semiconductor materials that can provide desired etching selectivity, desired oxidation rate differences, and/or desired performance characteristics (e.g., materials that maximize current flow).

In some embodiments, the semiconductor layers 102a-102c and 104a-104c are formed using multiple epitaxial growth operations. Each of the semiconductor layers 102a-102c and 104a-104c may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof.

In some embodiments, the semiconductor layers 102a-102c and 104a-104c are grown in-situ in the same process chamber. In some embodiments, the growth of the semiconductor layers 102a-102c and 104a-104c are alternately and sequentially performed in the same process chamber to complete the formation of the semiconductor stack. In some embodiments, the vacuum of the process chamber is not broken before the epitaxial growth of the semiconductor stack is accomplished.

Afterwards, hard mask elements are formed over the semiconductor stack to assist in a subsequent patterning of the semiconductor stack. Each of the hard mask elements may include a first mask layer 108 and a second mask layer 110. The first mask layer 108 and the second mask layer 110 may be made of different materials. One or more photolithography processes and one or more etching processes are used to pattern the semiconductor stack into multiple fin structures. The fin structures may be patterned by any suitable method. For example, the fin structures may be patterned using one or more photolithography processes, including double-patterning or multi-patterning processes. Double-patterning or multi-patterning processes may combine photolithography and self-aligned processes, allowing patterns to be created that have, for example, pitches smaller than what is otherwise obtainable using a single, direct photolithography process.

The semiconductor stack is partially removed to form multiple fin structures (including fin structures 106A and 106B) and multiple trenches 112, as shown in FIG. 2B. Each of the fin structures 106A-106B may include portions of the semiconductor layers 102a-102c and 104a-104c and multiple semiconductor fins (including semiconductor fins 101A and 101B), as shown in FIG. 2B. The semiconductor substrate 100 may also be partially removed during the etching process that forms the fin structures. Protruding portions of the semiconductor substrate 100 that remain form the semiconductor fins 101A and 101B.

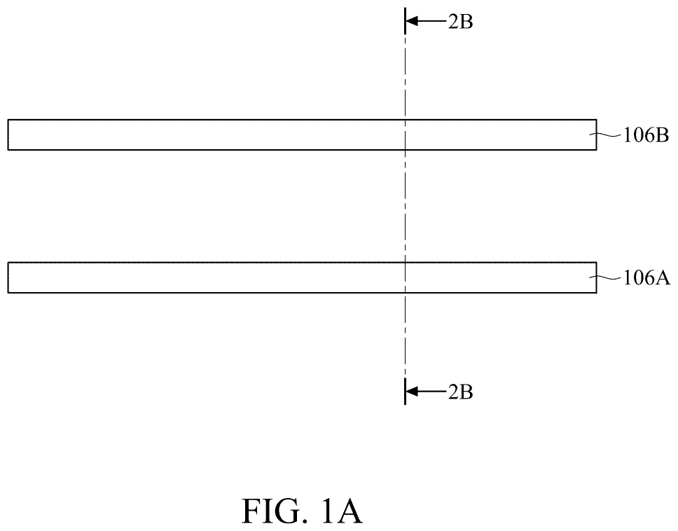

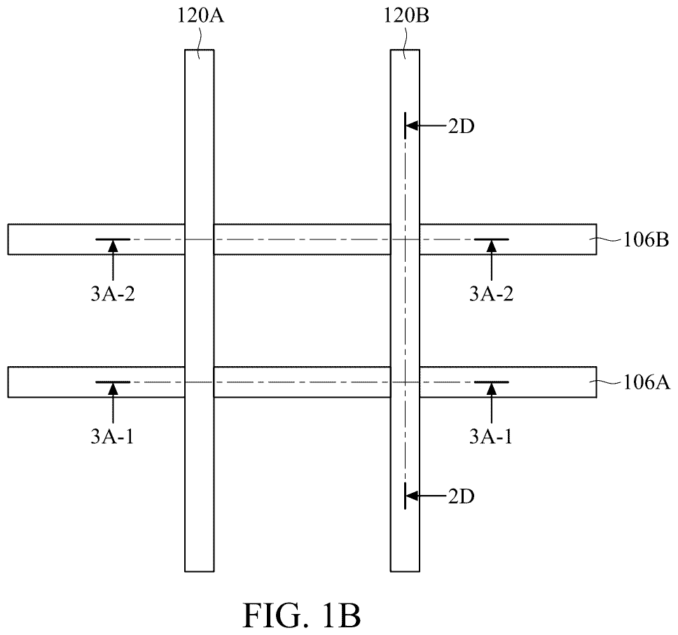

FIGS. 1A-1B are top views of various stages of a process for forming a portion of a semiconductor device structure, in accordance with some embodiments. As shown in FIG. 1A, multiple fin structures 106A and 106B are formed, in accordance with some embodiments. In some embodiments, the fin structures 106A and 106B are oriented lengthwise. In some embodiments, the extending directions of the fin structures 106A and 106B are substantially parallel to each other, as shown in FIG. 1A. In some embodiments, FIG. 2B is a cross-sectional view of the structure taken along the line 2B-2B in FIG. 1A.

Afterwards, as shown in FIG. 2C, an isolation structure 115 is formed to surround lower portions of the fin structures 106A and 106B, in accordance with some embodiments. In some embodiments, the isolation structure 115 includes dielectric fillings 114 and a liner layer 113 that is adjacent to the semiconductor fins 101A and 101B.

In some embodiments, one or more dielectric layers for forming the dielectric fillings 114 are deposited over the fin structures 106A and 106B and the semiconductor substrate 100. The dielectric layers may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, one or more other suitable materials, or a combination thereof. The liner layer 113 may be made of or include silicon nitride, silicon oxynitride, silicon carbide, silicon oxycarbide, one or more other suitable materials, or a combination thereof. The dielectric layers and the liner layer 113 may be deposited using a flowable chemical vapor deposition (FCVD) process, an atomic layer deposition (ALD) process, a chemical vapor deposition (CVD) process, one or more other applicable processes, or a combination thereof.

Afterwards, a planarization process is used to partially remove the dielectric layers and the liner layer 113. The hard mask elements (including the first mask layer 108 and the second mask layer 110) may also function as a stop layer of the planarization process. The planarization process may include a chemical mechanical polishing (CMP) process, a grinding process, a dry polishing process, an etching process, one or more other applicable processes, or a combination thereof.

Afterwards, one or more etching back processes are used to partially remove the dielectric layers and the liner layer 113. As a result, the remaining portion of the dielectric layers forms the dielectric fillings 114 of the isolation structure 115. Upper portions of the fin structures 106A and 106B protrude from the top surface of the isolation structure 115, as shown in FIG. 2C.

In some embodiments, the etching back process for forming the isolation structure 115 is carefully controlled to ensure that the topmost surface of the isolation structure 115 is positioned at a suitable height level, as shown in FIG. 2C. In some embodiments, the topmost surface of the isolation structure 115 is below the bottommost surface of the semiconductor layer 102a that functions as a sacrificial layer.

Afterwards, the hard mask elements (including the first mask layer 108 and the second mask layer 110) are removed. Alternatively, in some other embodiments, the hard mask elements are removed or consumed during the planarization process and/or the etching back process that forms the isolation structure 115.

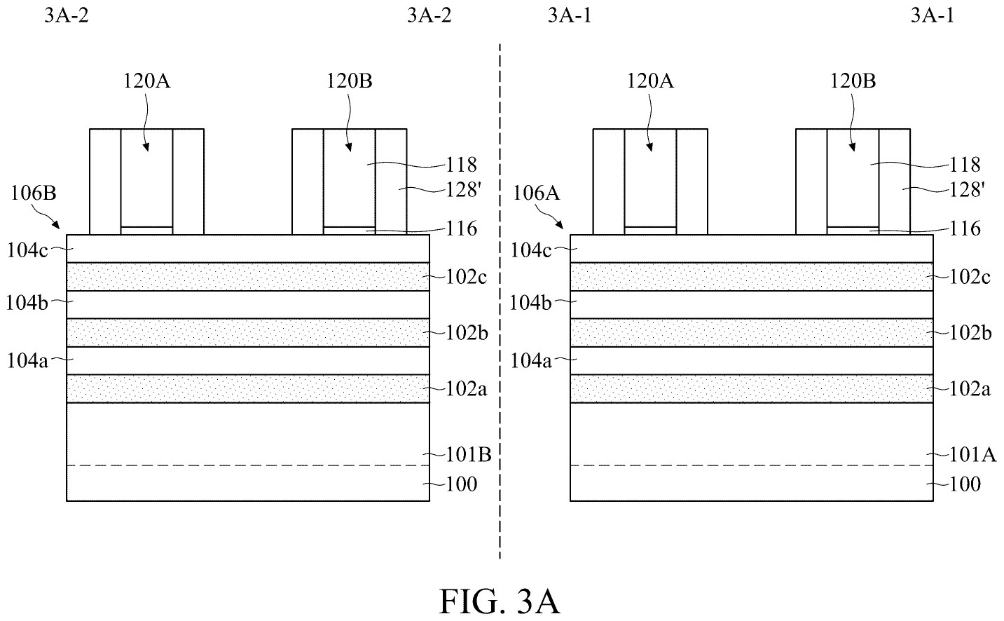

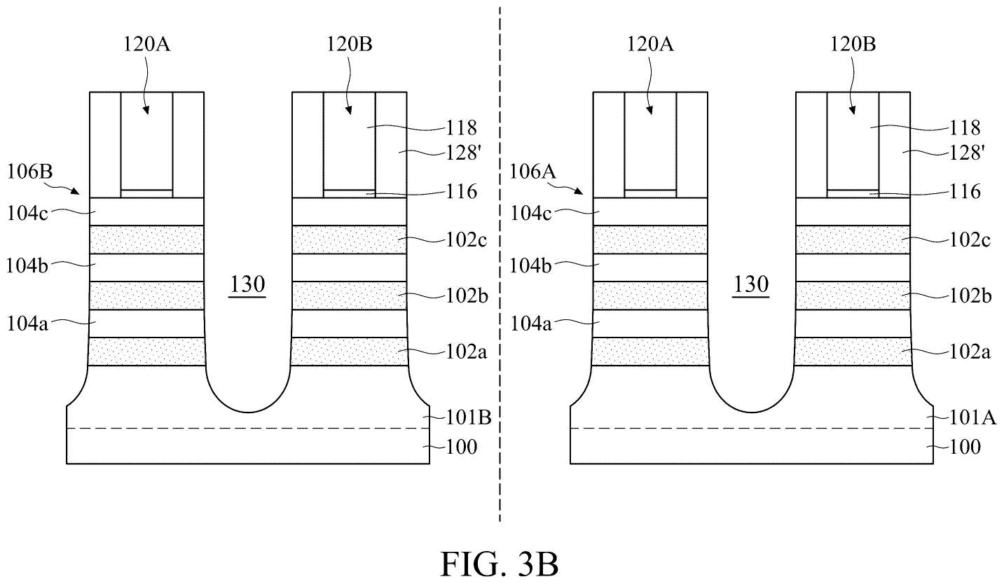

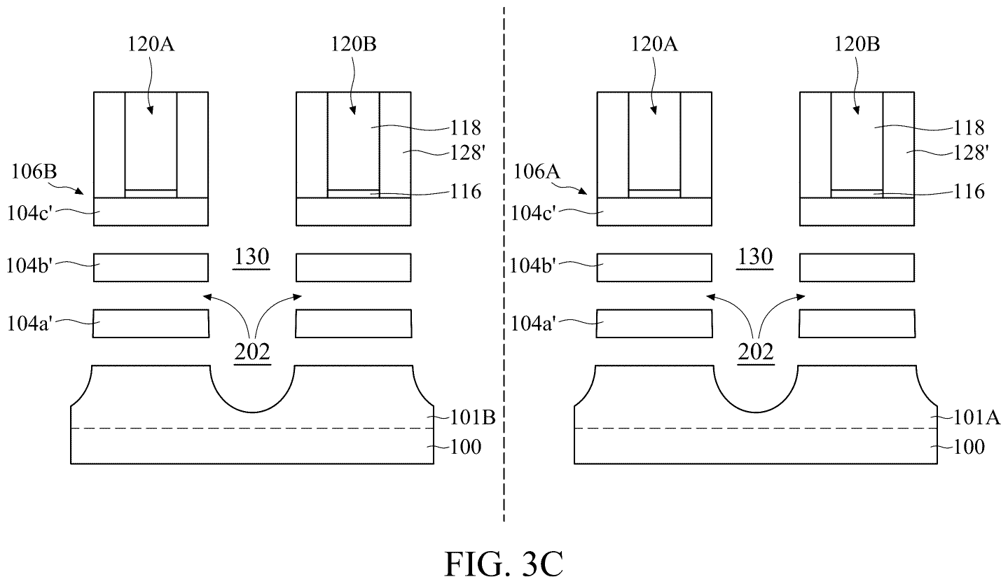

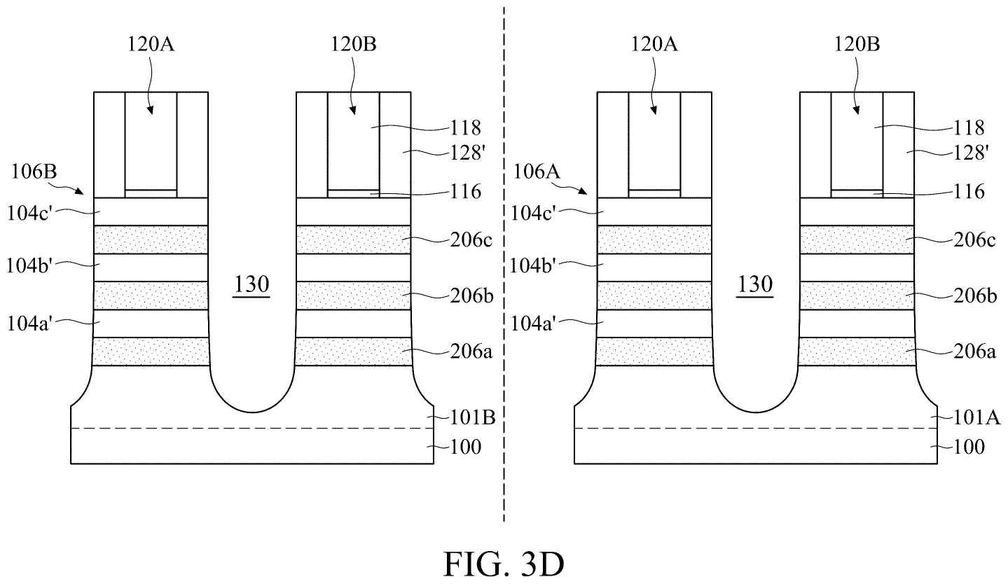

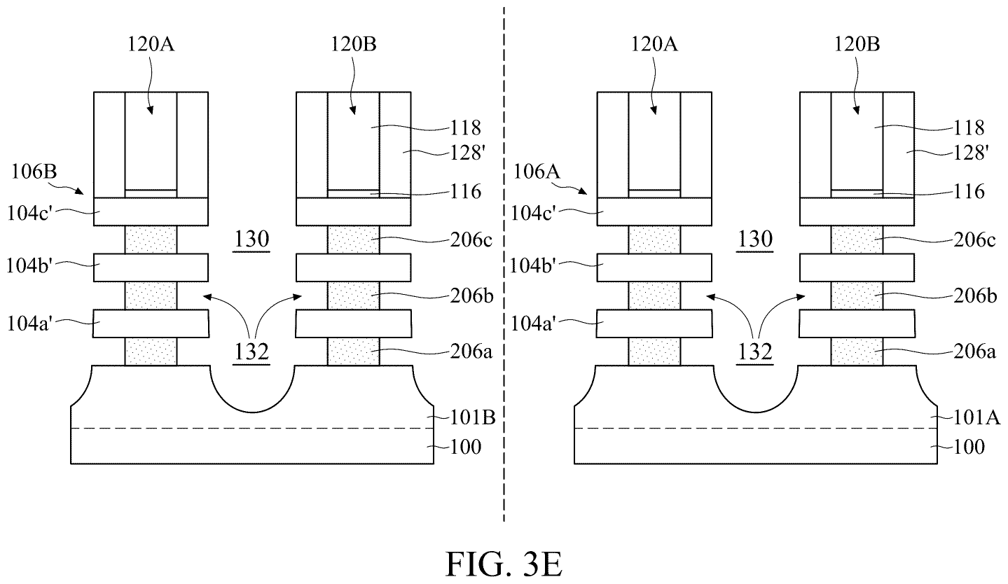

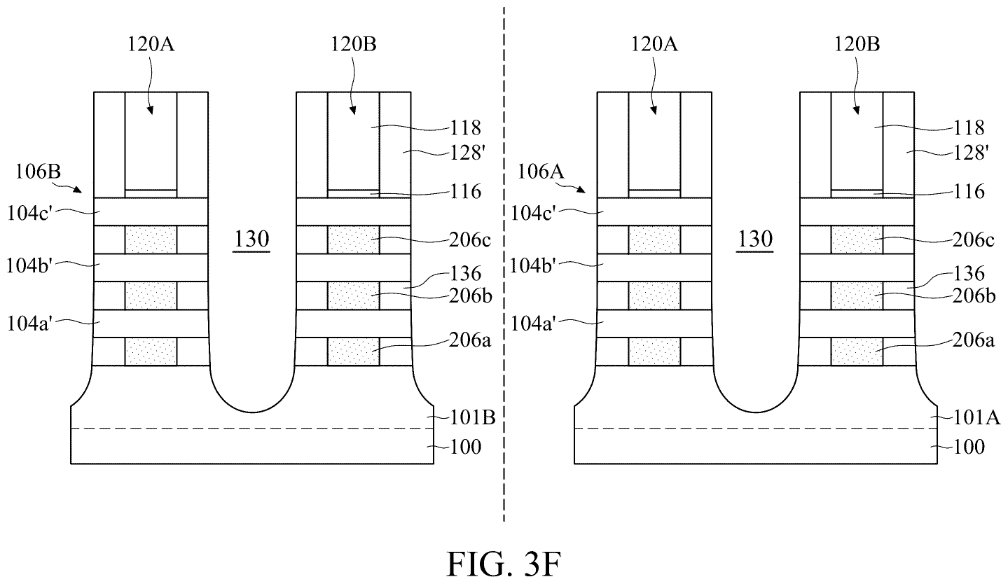

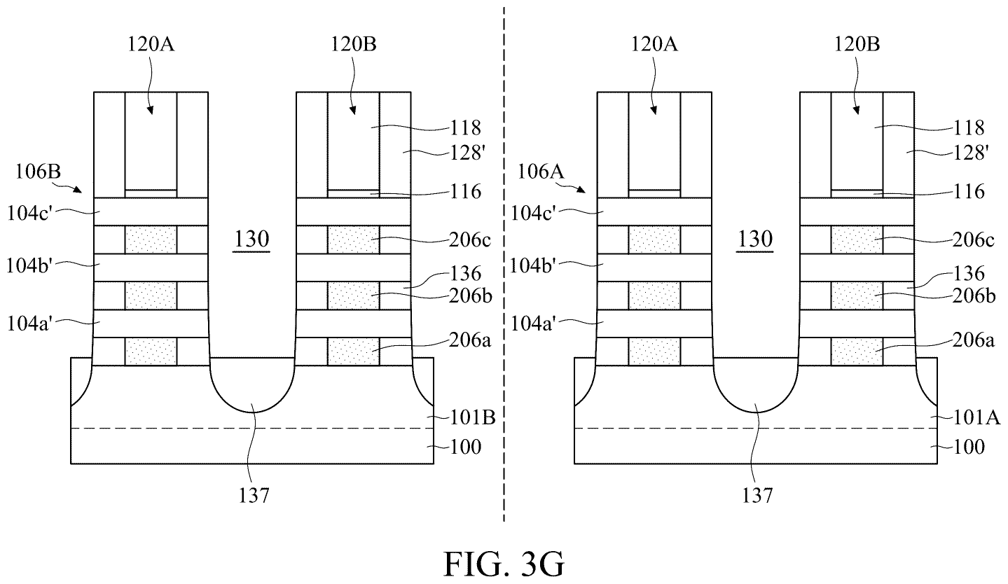

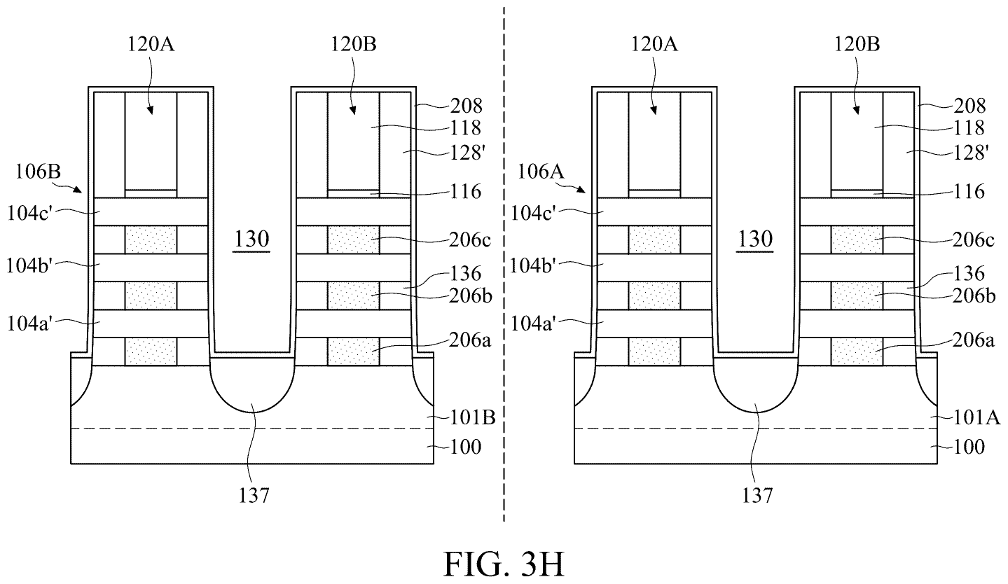

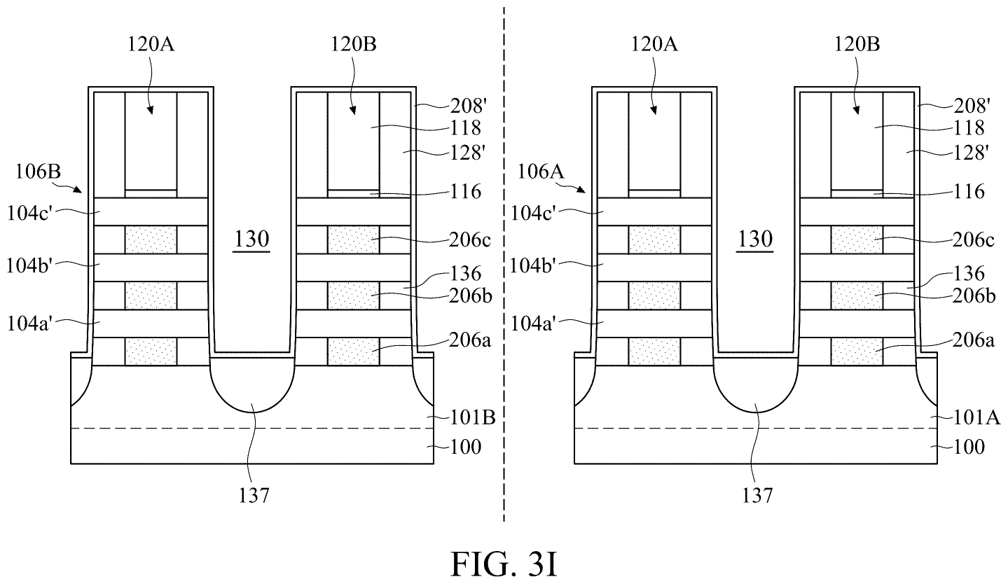

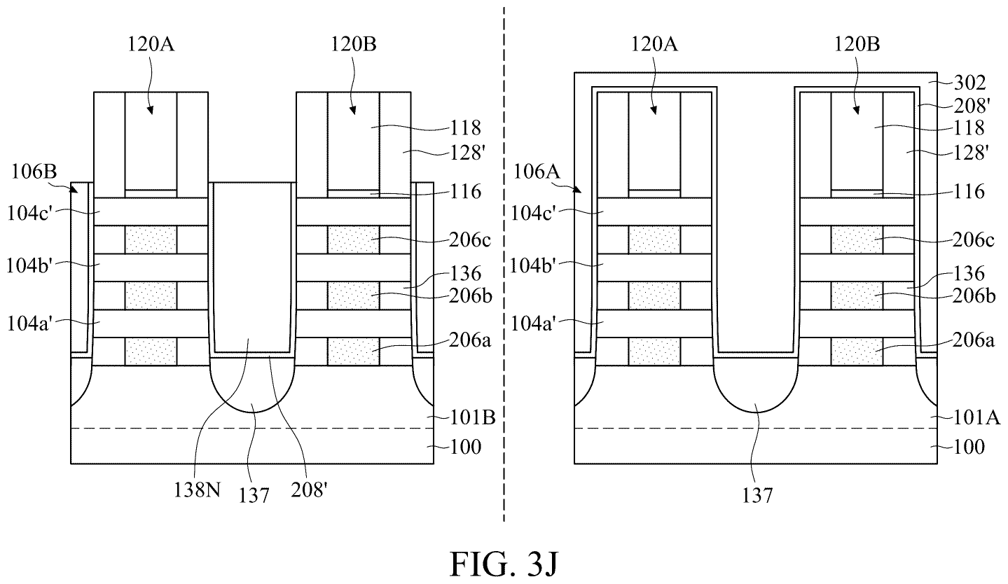

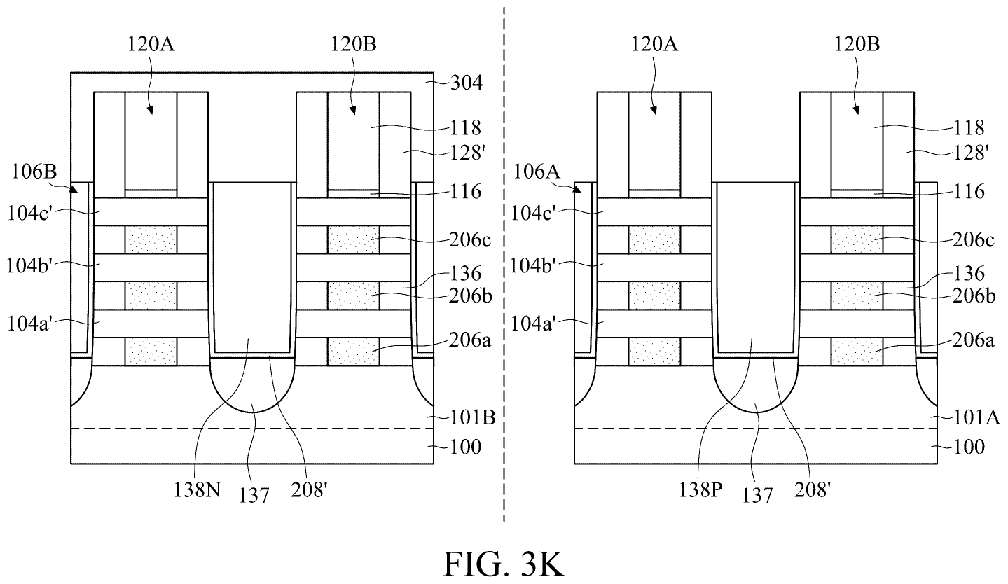

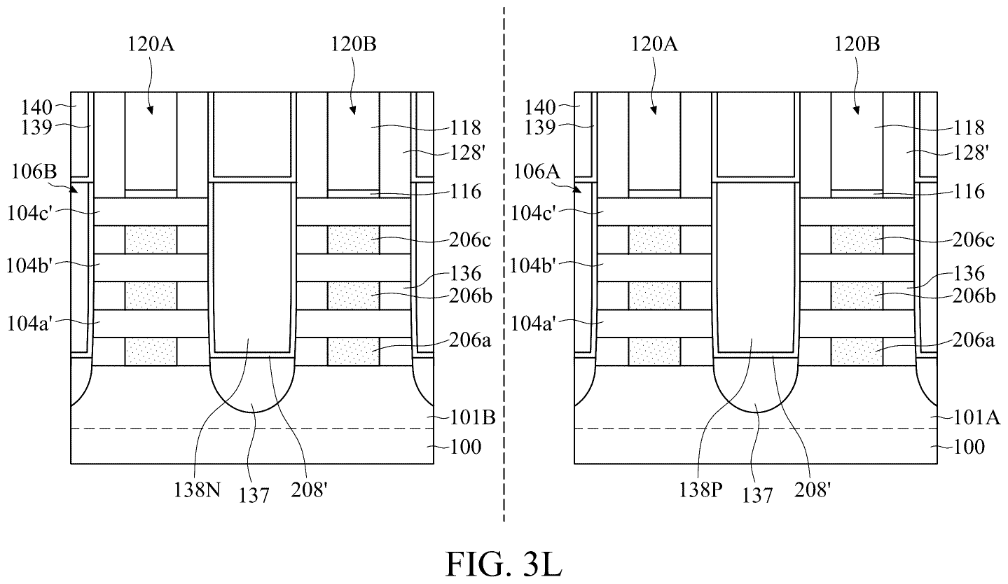

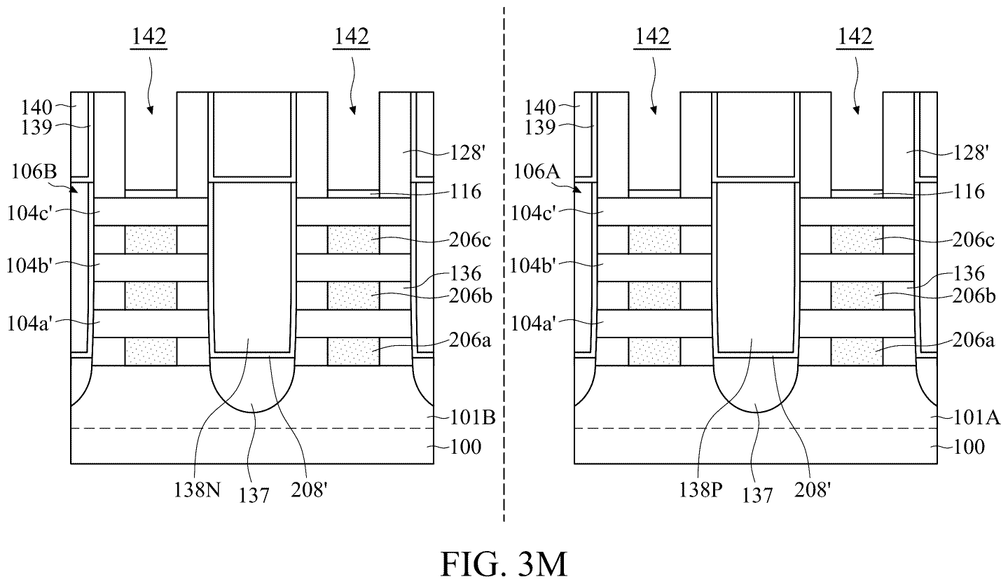

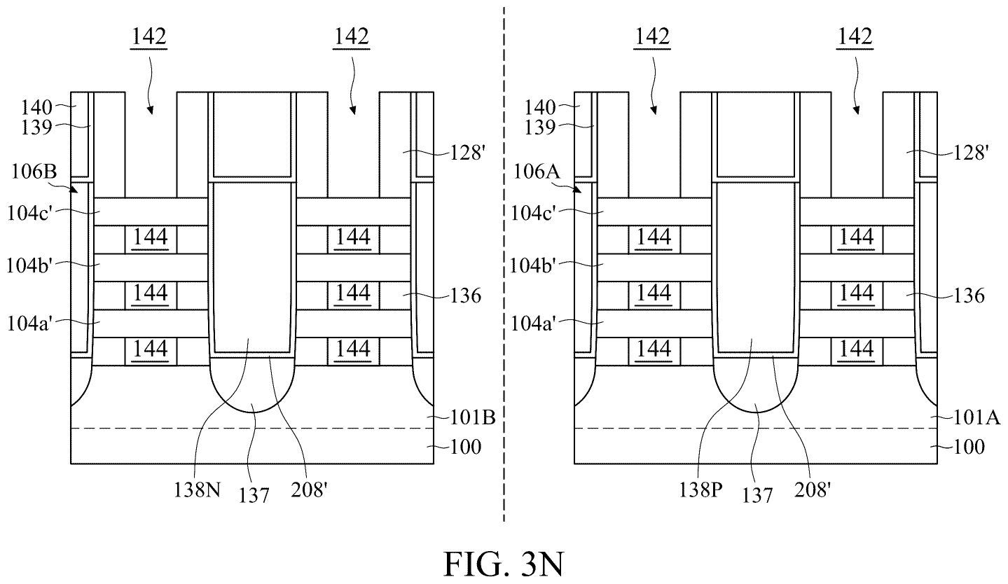

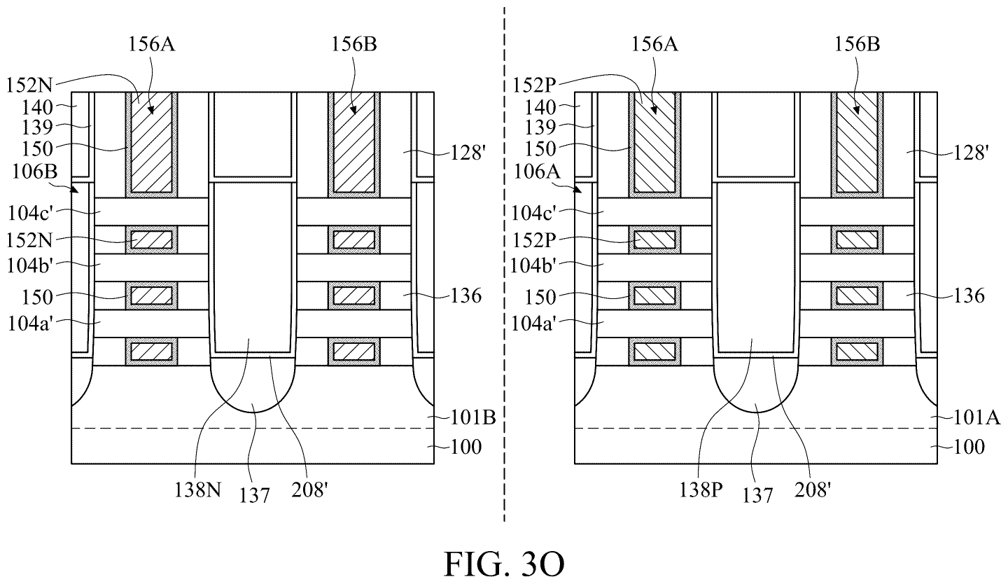

Afterwards, dummy gate stacks 120A and 120B are formed to extend across the fin structures 106A and 106B, as shown in FIG. 1B in accordance with some embodiments. In some embodiments, FIG. 2D is a cross-sectional view of the structure taken along the line 2D-2D in FIG. 1B. FIGS. 3A-3O are cross-sectional views of various stages of a process for forming portions of a semiconductor device structure, in accordance with some embodiments. In some embodiments, FIG. 3A is a cross-sectional view of two portions of the structure taken along the lines 3A-1 to 3A-1 and 3A-2 to 3A-2 in FIG. 1B.

As shown in FIGS. 1B, 2D, and 3A, the dummy gate stacks 120A and 120B partially cover and extend across the fin structures 106A and 106B, in accordance with some embodiments. In some embodiments, the dummy gate stacks 120A and 120B partially cover the fin structures 106A and 106B. As shown in FIG. 2D, the dummy gate stack 120B extends across and is wrapped around the fin structures 106A and 106B. As shown in FIG. 1B, other portions of the fin structures 106A and 106B are exposed without being covered by the dummy gate stack 120A or 120B.

As shown in FIGS. 2D and 3A, each of the dummy gate stacks 120A and 120B includes a dummy gate dielectric layer 116 and a dummy gate electrode 118. The dummy gate dielectric layer 116 may be made of or include silicon oxide or another suitable material. The dummy gate electrodes 118 may be made of or include polysilicon or another suitable material.

In some embodiments, a dummy gate dielectric material layer and a dummy gate electrode layer are sequentially deposited over the isolation structure 115 and the fin structures 106A and 106B. The dummy gate dielectric material layer may be deposited using an ALD process, a CVD process, one or more other applicable processes, or a combination thereof. The dummy gate electrode layer may be deposited using a CVD process. Afterwards, the dummy gate dielectric material layer and the dummy gate electrode layer are patterned to form the dummy gate stacks 120A and 120B.

In some embodiments, hard mask elements are used to assist in the patterning process for forming the dummy gate stacks 120A and 120B. With the hard mask elements as an etching mask, one or more etching processes are used to partially remove the dummy gate dielectric material layer and the dummy gate electrode layer. As a result, remaining portions of the dummy gate dielectric material layer and the dummy gate electrode layer form the dummy gate stacks 120A and 120B.

As shown in FIG. 3A, gate spacers 128′ are then formed over the sidewalls of the dummy gate stacks 120A and 120B, in accordance with some embodiments. In some embodiments, one or more spacer layers are deposited over the dummy gate stacks 120A and 120B and the fin structures 106A and 106B. The spacer layers extend along the tops and sidewalls of the dummy gate stacks 120A and 120B.

The spacer layers may be made of or include silicon nitride, silicon oxynitride, carbon-containing silicon nitride, carbon-containing silicon oxynitride, silicon oxide, carbon-containing silicon oxide, aluminum oxide, hafnium oxide, one or more other suitable materials, or a combination thereof. In some embodiments, one or more of the spacer layers is/are made of a high-k material. The spacer layers may be deposited using a CVD process, an ALD process, a physical vapor deposition (PVD) process, another applicable process, or a combination thereof.

Afterwards, the spacer layers are partially removed, in accordance with some embodiments. One or more anisotropic etching processes may be used to partially remove the spacer layers. As a result, remaining portions of the spacer layers form the gate spacers 128′. The gate spacers 128′ extend along the sidewalls of the dummy gate stacks 120A and 120B, as shown in FIG. 3A.

As shown in FIG. 3B, the fin structures 106A and 106B are partially removed, in accordance with some embodiments. As a result, multiple recesses 130 are formed. The recesses 130 expose the side edges of the semiconductor layers 102a-102c and 104a-104c. The recesses 130 may be used to contain epitaxial structures (such as source/drain structures) that will be formed later. Source/drain structures (or region(s)) may refer to a source or a drain, individually or collectively dependent upon the context. In some embodiments, the recesses 130 formed in the fin structure 106A are used for containing p-type doped epitaxial structures that will be formed later. In some embodiments, the recesses 130 formed in the fin structure 106B are used for containing n-type doped epitaxial structures that will be formed later.

One or more etching processes may be used to form the recesses 130. In some embodiments, a dry etching process is used to form the recesses 130. Alternatively, a wet etching process may be used to form the recesses 130. The recesses 130 penetrate into the fin structures 106A and 106B. In some embodiments, the recesses 130 further extend into the semiconductor fins 101A and 101B, as shown in FIG. 3B.

In some embodiments, the recesses 130 have substantially vertical sidewalls. In these cases, due to the profile of the recesses 130, an upper semiconductor layer (such as the semiconductor layer 104c) is substantially as wide as a lower semiconductor layer (such as the semiconductor layer 104b).

However, embodiments of the disclosure have Various variations. In some other embodiments, each of the recesses 130 has slanted sidewalls. Upper portions of the recesses 130 are larger (or wider) than lower portions of the recesses 130. In these cases, due to the profile of the recesses 130, an upper semiconductor layer (such as the semiconductor layer 104c) is shorter than a lower semiconductor layer (such as the semiconductor layer 104b).

Afterwards, the semiconductor layers 102a-102c, which serve as sacrificial layers, are removed. As a result, the structure shown in FIG. 3C is formed, in accordance with some embodiments. One or more etching processes may be used to remove the semiconductor layers 102a-102c. After the removal of the semiconductor layers 102a-102c, multiple recesses 202 are formed, as shown in FIG. 3C. The remaining portions of the semiconductor layers 104a-104c that are released from the semiconductor layers 102a-102c form multiple semiconductor nanostructures 104a′, 104b′, and 104c′, as shown in FIG. 3C. With the support of the dummy gate stacks 120A and 120B, the semiconductor nanostructures 104a′-104c′ are securely held in place.

As shown in FIG. 3D, multiple dielectric nanostructures 206a, 206b, and 206c are formed in the recesses 202, in accordance with some embodiments. In some embodiments, a dielectric layer is deposited to overfill the recesses 202 and to surround the semiconductor layers 104a-104c, in accordance with some embodiments. The dielectric layer may function as a sacrificial layer and will be removed later. The dielectric layer may be made of an oxide material. The dielectric layer may be made of or include silicon oxide, silicon oxynitride, another suitable material, or a combination thereof. The dielectric layer may be deposited using a CVD process, an ALD process, another applicable process, or a combination thereof.

Afterwards, the dielectric layer is partially removed, in accordance with some embodiments. The portion of the dielectric layer outside of the recesses 202 are removed. As a result, the remaining portions of the dielectric layer form multiple dielectric nanostructures 206a, 206b, and 206c, as shown in FIG. 3D.

Afterwards, as shown in FIG. 3E, the dielectric nanostructures 206a-206c are laterally etched, in accordance with some embodiments. As a result, the side edges of the dielectric nanostructures 206a-206c retreat from the side edges of the semiconductor nanostructures 104a′-104c′. The side edges of the dielectric nanostructures 206a-206c are pulled back. As shown in FIG. 3E, recesses 132 are formed due to the lateral etching of the dielectric nanostructures 206a-206c. The recesses 132 may be used to contain inner spacers that will be formed later. The dielectric nanostructures 206a-206c may be laterally etched using a wet etching process, a dry etching process, or a combination thereof.

As shown in FIG. 3F, inner spacers 136 are formed in the recesses 132, in accordance with some embodiments. The inner spacers 136 cover the side edges of the dielectric nanostructures 206a-206c. The inner spacers 136 may be used to prevent subsequently formed epitaxial structures (which function as, for example, source/drain structures) from being damaged during a subsequent process for removing the dielectric nanostructures 206a-206c. In some embodiments, the inner spacers 136 are made of a low-k material that has a lower dielectric constant than that of silicon oxide. In these cases, the inner spacers 136 may also be used to reduce parasitic capacitance between the subsequently formed source/drain structures and the gate stacks. As a result, the operation speed of the semiconductor device structure may be improved.

In some embodiments, an insulating layer is deposited over the structure shown in FIG. 3E. The insulating layer covers the dummy gate stacks 120A and 120B and overfills the recesses 132. The insulating layer may be made of or include carbon-containing silicon nitride (SiCN), carbon-containing silicon oxynitride (SiOCN), carbon-containing silicon oxide (SiOC), silicon oxide, silicon nitride, aluminum oxide, hafnium oxide, one or more other suitable materials, or a combination thereof. In some embodiments, the insulating layer is a single layer. In some other embodiments, the insulating layer includes multiple sub-layers. Some of the sub-layers may be made of different materials and/or contain different compositions. The insulating layer may be deposited using a CVD process, an ALD process, one or more other applicable processes, or a combination thereof.

Afterwards, one or more etching processes are used to partially remove the insulating layer, in accordance with some embodiments. The portions of the insulating layer outside of the recesses 132 may be removed. The remaining portions of the insulating layer form the inner spacers 136, as shown in FIG. 3F. The etching process may include a dry etching process, a wet etching process, or a combination thereof. In some embodiments, the compositions of the inner spacers 136 and the gate spacers 128′ are different, so as to provide etching selectivity between the inner spacers 136 and the gate spacers 128′. In some embodiments, the compositions of the inner spacers 136 and the dielectric nanostructures 206a-206c are different, so as to provide etching selectivity between the inner spacers 136 and the dielectric nanostructures 206a-206c.

As shown in FIG. 3G, semiconductor isolation structures 137 are formed over the bottoms of the recesses 130, in accordance with some embodiments. In some embodiments, the semiconductor isolation structures 137 are epitaxial structures that are undoped. In some embodiments, the semiconductor isolation structures 137 are substantially free of n-type dopants or p-type dopants.

The semiconductor isolation structures 137 may be made of or include silicon, silicon germanium, another suitable material, or a combination thereof. The semiconductor isolation structures 137 may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, another applicable process, or a combination thereof. In some embodiments, the formation of the semiconductor isolation structures 137 involve one or more etching processes that are used to fine-tune the profiles of the semiconductor isolation structures 137. In some embodiments, the semiconductor isolation structures 137 on the semiconductor fins 101A and 101B are formed simultaneously.

In some embodiments, the semiconductor isolation structures 137 are formed to have substantially planar top surfaces, as shown in FIG. 3G. In some embodiments, the top surfaces of the semiconductor isolation structures 137 are positioned at a height level that is lower than the bottom surface of the semiconductor nanostructure 104a′. In some embodiments, the top surfaces of the semiconductor isolation structures 137 and the top surfaces of the semiconductor fins 101A and 101B are substantially level. In some embodiments, the top surfaces of the semiconductor isolation structures 137 are higher than the top surfaces of the semiconductor fins 101A and 101B. In some embodiments, the semiconductor isolation structures 137 are in direct contact with some of the inner spacers 136, as shown in FIG. 3G.

Many variations and/or modifications can be made to embodiments of the disclosure. In some other embodiments, the semiconductor isolation structures 137 are not formed.

As shown in FIG. 3H, a continuous semiconductor layer 208 is deposited, in accordance with some embodiments. The continuous semiconductor layer 208 extends along the sidewalls of the dummy gate stacks 120A and 120B. The continuous semiconductor layer 208 further extends along the side edges of the semiconductor nanostructures 104a′-104c′ and the inner spacers 136, as shown in FIG. 3H. In some embodiments, the continuous semiconductor layer 208 extends along the side edges of the semiconductor nanostructures 104a′-104c′ and the inner spacers 136 in a conformal manner. The thickness of the continuous semiconductor layer 208 may be within a range from about 0.5 nm to about 2 nm.

In some embodiments, the continuous semiconductor layer 208 is an amorphous semiconductor layer. In some embodiments, the continuous semiconductor layer 208 is made of silicon. The continuous semiconductor layer 208 may be deposited using a CVD process or another applicable process. The continuous semiconductor layer 208 may be deposited at a temperature that is within a range from about 300 degrees C. to about 500 degrees C. Due to the low-temperature process, the continuous semiconductor layer 208 may be non-selectively deposited on the side edges of both the semiconductor nanostructures 104a′-104c′ and the inner spacers 136. The adhesion between the continuous semiconductor layer 208 and the inner spacers 136 is sufficient.

As shown in FIG. 31, the continuous semiconductor layer 208 is then crystallized to form a crystallized semiconductor layer 208′, in accordance with some embodiments. In some embodiments, the crystallized semiconductor layer 208′ is single crystalline. The thickness of the continuous semiconductor layer 208 may be within a range from about 0.5 nm to about 2 nm. In some cases, if the continuous semiconductor layer 208 is thinner than about 0.5 nm or thicker than about 2 nm, its crystallization may be adversely affected. the In some embodiments, the crystallized semiconductor layer 208′ is formed using a laser annealing process, an ultra sub-second annealing (uSSA) process, another applicable process, or a combination thereof.

In some embodiments, the continuous semiconductor layer 208 is irradiated with a laser beam to convert the continuous semiconductor layer 208 into the crystallized semiconductor layer 208′. A melt laser annealing process may be used. For example, local laser irradiation in scan mode is used to irradiate the continuous semiconductor layer 208 with a laser beam. The irradiated laser beam may have a wavelength that is larger than about 1300 nm. The operation time may be within a range from about 1 nanosecond to about 1 microsecond. In some embodiments, due to the laser irradiation, the temperature of the irradiated portions is increased to be within a range from about 1200 degrees C. to about 1300 degrees C.

In some cases, if the temperature of the continuous semiconductor layer 208 is below approximately 1200 degrees C., it may not convert sufficiently into the crystallized semiconductor layer 208′. In some other cases, if the temperature of the continuous semiconductor layer 208 is above approximately 1300 degrees C., the nearby elements may be damaged.

In some embodiments, the continuous semiconductor layer 208 is thermally annealed to convert the continuous semiconductor layer 208 into the crystallized semiconductor layer 208′. For example, the continuous semiconductor layer 208 is annealed using an ultra sub-second annealing (uSSA) process. The annealing time may be within a range from about 10⁻⁶ seconds to about 10⁻³ seconds. In some embodiments, the annealing temperature is within a range from about 1200 degrees C. to about 1300 degrees C.

In some cases, if the annealing time is shorter than about 10⁻⁶ seconds, the continuous semiconductor layer 208 may not be converted sufficiently into the crystallized semiconductor layer 208′. In some other cases, if the annealing time is longer than about 10⁻³ seconds, the nearby elements may be damaged. In some cases, if the temperature of the continuous semiconductor layer 208 is below approximately 1200 degrees C., it may not convert sufficiently into the crystallized semiconductor layer 208′. In some other cases, if the temperature of the continuous semiconductor layer 208 is above approximately 1300 degrees C., the nearby elements may be damaged due to the high temperature.

In some embodiments, only the laser annealing process is used to convert the continuous semiconductor layer 208 into the crystallized semiconductor layer 208′. In some other embodiments, only the uSSA process is used to convert the continuous semiconductor layer 208 into the crystallized semiconductor layer 208′. In some other embodiments, both the laser annealing process and the uSSA process are used to convert the continuous semiconductor layer 208 into the crystallized semiconductor layer 208′. In some embodiments, the laser annealing process and the uSSA process are used simultaneously to convert the continuous semiconductor layer 208 into the crystallized semiconductor layer 208′. In some other embodiments, the laser annealing process and the uSSA process are used sequentially to convert the continuous semiconductor layer 208 into the crystallized semiconductor layer 208′. In some embodiments, the laser annealing process is performed before the uSSA process. In some other embodiments, the laser annealing process is performed after the uSSA process.

As shown in FIG. 3J, a mask element 302 is formed to cover the fin structure 106A, the semiconductor isolation structures 137 on the semiconductor fin 101A, and portions of the dummy gate stacks 120A and 120B near the fin structure 106A, in accordance with some embodiments. The fin structure 106B, the semiconductor isolation structures 137 on the semiconductor fin 101B, and portions of the dummy gate stacks 120A and 120B near the fin structure 106B are exposed without being covered by the mask element 302.

Afterwards, epitaxial structures 138N are formed on the crystallized semiconductor layer 208′ that is exposed, as shown in FIG. 3J in accordance with some embodiments. In some embodiments, the epitaxial structures 138N fill the recesses 130 that are not covered by the mask element 302, as shown in FIG. 3F. In some embodiments, the top surfaces of the epitaxial structures 138N are higher than the top surface of the dummy gate dielectric layer 116. In some other embodiments, the epitaxial structures 138N partially fill the recesses 130.

In some embodiments, some of the semiconductor nanostructures 104a′-104c′ are sandwiched between the epitaxial structures 138N. In some embodiments, the epitaxial structures 138N are n-type doped epitaxial structures. The epitaxial structures 138N may include epitaxially grown silicon, epitaxially grown silicon germanium (SiGe), or another suitable epitaxially grown semiconductor material.

In some embodiments, the epitaxial structures 138N are formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof. In some embodiments, the formation of the epitaxial structures 138N involves one or more etching processes that are used to fine-tune the shapes of the epitaxial structures 138N. In some embodiments, the portions of the crystallized semiconductor layer 208′ that extend along the exposed portion of the dummy gate stacks 120A and 120B are removed during the one or more etching processes, as shown in FIG. 3J.

In some embodiments, the epitaxial structures 138N are doped with one or more suitable n-type dopants. For example, the epitaxial structures 138N are Si source/drain features that are doped with phosphor (P), antimony (Sb), arsenic (As) or another suitable dopant. In some embodiments, each of the epitaxial structures 138N has a first region and a second region over the first region. The second region may have a greater dopant concentration than that of the first region.

In some embodiments, the epitaxial structures 138N are doped in-situ during their epitaxial growth. The initial reaction gas mixture for forming the epitaxial structures 138N contains dopants. In some other embodiments, the epitaxial structures 138N are not doped during the growth of the epitaxial structures 138N. Instead, after the formation of the epitaxial structures 138N, the epitaxial structures 138N are doped in a subsequent process. In some embodiments, the doping is achieved by using an ion implantation process, a plasma immersion ion implantation process, a gas and/or solid source diffusion process, one or more other applicable processes, or a combination thereof. In some embodiments, the epitaxial structures 138N are further exposed to one or more annealing processes to activate the dopants. For example, a rapid thermal annealing process is used.

As shown in FIG. 3J, the side edges of the inner spacers 136 are covered with the crystallized semiconductor layer 208′. The epitaxial structures 138N are grown on the semiconductor surface of the crystallized semiconductor layer 208′ rather than directly on the dielectric surfaces of the inner spacers 136. As a result, the epitaxial structures 138N exhibit good crystal quality due to their growth on the crystallized semiconductor layer 208′. In some embodiments, the epitaxial structures 138N have high crystallinity. In some embodiments, the epitaxial structures 138N are single crystalline.

As shown in FIG. 3K, the mask element 302 is removed, and a mask element 304 is formed to cover the epitaxial structures 138N, in accordance with some embodiments. After the removal of the mask element 302, the fin structure 106A and the crystallized semiconductor layer 208′ on the semiconductor fin 101A are exposed.

Afterwards, epitaxial structures 138P are formed on the crystallized semiconductor layer 208′, as shown in FIG. 3K in accordance with some embodiments. In some embodiments, the epitaxial structures 138P fill the recesses 130 that are not covered by the mask element 304. In some embodiments, the top surfaces of the epitaxial structures 138P are higher than the top surface of the dummy gate dielectric layer 116. In some other embodiments, the epitaxial structures 138P partially fill the recesses 130.

In some embodiments, some of the semiconductor nanostructures 104a′-104c′ are sandwiched between the epitaxial structures 138P. In some embodiments, the epitaxial structures 138P are p-type epitaxial structures. In some embodiments, the epitaxial structures 138P contain germanium. The epitaxial structures 138P may include epitaxially grown silicon germanium or another suitable epitaxially grown semiconductor material.

In some embodiments, the epitaxial structures 138P are formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof. In some embodiments, the formation of the epitaxial structures 138P involves one or more etching processes that are used to fine-tune the shapes of the epitaxial structures 138P. In some embodiments, the portions of the crystallized semiconductor layer 208′ that extend along the exposed portion of the dummy gate stacks 120A and 120B are removed during the one or more etching processes, as shown in FIG. 3K.

In some embodiments, the epitaxial structures 138P are doped with one or more suitable p-type dopants. For example, the epitaxial structures 138P are SiGe source/drain features that are doped with boron (B), gallium (Ga), indium (In), or another suitable dopant. In some embodiments, each of the epitaxial structures 138P has a first region and a second region over the first region. The second region may have a greater dopant concentration than that of the first region.

In some embodiments, the epitaxial structures 138P are doped in-situ during their epitaxial growth. The initial reaction gas mixture for forming the epitaxial structures 138P contains dopants. In some other embodiments, the epitaxial structures 138P are not doped during the growth of the epitaxial structures 138P. Instead, after the formation of the epitaxial structures 138P, the epitaxial structures 138P are doped in a subsequent process. In some embodiments, the doping is achieved by using an ion implantation process, a plasma immersion ion implantation process, a gas and/or solid source diffusion process, one or more other applicable processes, or a combination thereof. In some embodiments, the epitaxial structures 138P are further exposed to one or more annealing processes to activate the dopants. For example, a rapid thermal annealing process is used.

As shown in FIG. 3K, the side edges of the inner spacers 136 are covered with the crystallized semiconductor layer 208′. The epitaxial structures 138P are grown on the semiconductor surface of the crystallized semiconductor layer 208′ rather than directly on the dielectric surfaces of the inner spacers 136. As a result, the epitaxial structures 138P exhibit good crystal quality due to their growth on the crystallized semiconductor layer 208′. In some embodiments, the epitaxial structures 138P have high crystallinity. In some embodiments, the epitaxial structures 138P are single crystalline.

In some embodiments, the crystallized semiconductor layer 208′ has a thickness that is within a range from about 0.5 nm to about 2 nm. In some cases, if the crystallized semiconductor layer 208′ is thinner than about 0.5 nm, it may adversely affect the growth of the epitaxial structures 138P or 138N. The performance and reliability of the semiconductor device structure may be negatively affected. In some other cases, if the crystallized semiconductor layer 208′ is thicker than about 2 nm, it may be hard for the dopants from the epitaxial structures 138P or 138N to diffuse towards the edges of the semiconductor nanostructures 104a′-104c′. The performance and reliability of the semiconductor device structure may be negatively affected.

In some embodiments illustrated in FIGS. 3J-3K, the epitaxial structures 138N are formed before the epitaxial structures 138P. However, embodiments of the disclosure are not limited thereto. Many variations and/or modifications can be made to embodiments of the disclosure. In some other embodiments, the epitaxial structures 138P are formed before the epitaxial structures 138N.

Afterwards, the mask element 304 is removed. As shown in FIG. 3L, a contact etch stop layer 139 and a dielectric layer 140 are then formed over the epitaxial structures 138N and 138P to laterally surround the dummy gate stacks 120A and 120B, in accordance with some embodiments. The contact etch stop layer 139 may be made of or include silicon nitride, silicon oxynitride, silicon carbide, aluminum oxide, another suitable material, or a combination thereof. The dielectric layer 140 may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, another suitable material, or a combination thereof.

In some embodiments, an etch stop material layer and a dielectric material layer are sequentially deposited. The etch stop material layer may be deposited using a CVD process, an ALD process, a PVD process, one or more other applicable processes, or a combination thereof. The dielectric material layer may be deposited using an FCVD process, a CVD process, an ALD process, another applicable process, or a combination thereof.

Afterwards, a planarization process is used to partially remove the etch stop material layer and the dielectric material layer. As a result, the remaining portions of the etch stop material layer and the dielectric material layer respectively form the contact etch stop layer 139 and the dielectric layer 140, as shown in FIG. 3L. The planarization process may include a CMP process, a grinding process, an etching process, a dry polishing process, one or more other applicable processes, or a combination thereof.

In some embodiments, the mask elements used for defining the dummy gate stacks 120A and 120B are removed during the planarization process. In some embodiments, after the planarization process, the top surfaces of the contact etch stop layer 139, the dielectric layer 140, and the dummy gate electrodes 118 are substantially level.

Afterwards, as shown in FIG. 3M, the dummy gate electrodes 118 are removed to form trenches 142 using one or more etching processes, in accordance with some embodiments. The trenches 142 are surrounded by the dielectric layer 140. The trenches 142 expose the dummy gate dielectric layer 116.

As shown in FIG. 3N, the dummy gate dielectric layer 116 and the dielectric nanostructures 206a-206c (which function as sacrificial layers) are removed, in accordance with some embodiments. In some embodiments, one or more etching processes are used to remove the dummy gate dielectric layer 116 and the dielectric nanostructures 206a-206c. As a result, recesses 144 are formed, as shown in FIG. 3N.

Due to high etching selectivity, the semiconductor nanostructures 104a′-104c′ are slightly (or substantially not) etched. The semiconductor nanostructures 104a′-104c′ suspended over the semiconductor fins 101A and 101B may function as the channel structures of transistors. In some other embodiments, the etchant used for removing the dielectric nanostructures 206a-206c also slightly removes the semiconductor nanostructures 104a′-104c′. As a result, the obtained semiconductor nanostructures 104a′-104c′ become thinner after the removal of the dielectric nanostructures 206a-206c.

After the removal of the dielectric nanostructures 206a-206c (which function as sacrificial layers), the recesses 144 are formed. The recesses 144 connect to the trench 142 and surround each of the semiconductor nanostructures 104a′-104c′. As shown in FIG. 3N, even if the recesses 144 between the semiconductor nanostructures 104a′-104c′ are formed, the semiconductor nanostructures 104a′-104c′ remain held by the neighboring elements including the epitaxial structures 138N, 138P, and the inner spacers 136. Therefore, after the removal of the dummy gate stacks 120A and 120B and the dielectric nanostructures 206a-206c (which function as sacrificial layers), the released semiconductor nanostructures 104a′-104c′ are prevented from falling.

During the removal of the dielectric nanostructures 206a-206c (which function as sacrificial layers), the inner spacers 136 protect the crystallized semiconductor layer 208′ and the epitaxial structures 138N and 138P from being etched or damaged. The quality and reliability of the semiconductor device structure are improved.

As shown in FIG. 3O, metal gate stacks 156A and 156B are formed to fill the trenches 142, in accordance with some embodiments. The metal gate stacks 156A and 156B further extend into the recesses 144 to wrap around each of the semiconductor nanostructures 104a′-104c′.

Each of the metal gate stacks 156A and 156B includes multiple metal gate stack layers. Each of the metal gate stacks 156A and 156B may include a gate dielectric layer 150 and metal gate electrodes 152P and 152N. Each of the metal gate electrodes 152P and 152N may include a work function layer. Each of the metal gate electrodes 152P and 152N may further include a conductive filling. In some embodiments, the formation of the metal gate stacks 156A and 156B involves the deposition of multiple metal gate stack layers over the dielectric layer 140 to fill the trenches 142 and the recesses 144. The metal gate stack layers extend into the recesses 144 to wrap around each of the semiconductor nanostructures 104a′-104c′.

In some embodiments, the gate dielectric layer 150 is made of or includes a dielectric material with high dielectric constant (high-K). The gate dielectric layer 150 may be made of or include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, one or more other suitable high-K materials, or a combination thereof. The gate dielectric layer 150 may be deposited using an ALD process, a CVD process, one or more other applicable processes, or a combination thereof.

In some embodiments, before the formation of the gate dielectric layer 150, an interfacial layers are formed on the surfaces of the semiconductor nanostructures 104a′-104c′. The interfacial layers are very thin and are made of, for example, silicon oxide or germanium oxide. In some embodiments, the interfacial layers are formed by applying an oxidizing agent on the surfaces of the semiconductor nanostructures 104a′-104c′. For example, a hydrogen peroxide-containing liquid may be applied or provided on the surfaces of the semiconductor nanostructures 104a′-104c′ so as to form the interfacial layers.

The work function layer of the metal gate electrodes 152P and 152N may be used to provide the desired work function for transistors to enhance device performance including improved threshold voltage. The metal gate electrodes 152P and 152N may have different work function layers. In some embodiments, the work function layer surrounding the semiconductor nanostructures 104a′-104c′of the fin structure 106A is used for forming a PMOS device. In these cases, the work function layer of the metal gate electrode 152P is a p-type work function layer. The p-type work function layer is capable of providing a work function value suitable for the device, such as equal to or greater than about 4.8 eV.

The p-type work function layer may include metal, metal carbide, metal nitride, other suitable materials, or a combination thereof. For example, the p-type metal includes tantalum nitride, tungsten nitride, titanium, titanium nitride, one or more other suitable materials, or a combination thereof.

In some embodiments, the work function layer surrounding the semiconductor nanostructures 104a′-104c′of the fin structure 106B is used for forming an NMOS device. The work function layer of the metal gate electrode 152N is an n-type work function layer. The n-type work function layer is capable of providing a work function value suitable for the device, such as equal to or less than about 4.5 eV.

The n-type work function layer may include metal, metal carbide, metal nitride, or a combination thereof. For example, the n-type work function layer includes titanium nitride, tantalum, tantalum nitride, one or more other suitable materials, or a combination thereof. In some embodiments, the n-type work function is an aluminum-containing layer. The aluminum-containing layer may be made of or include TiAlC, TiAlO, TiAlN, one or more other suitable materials, or a combination thereof.

The work function layer may also be made of or include hafnium, zirconium, titanium, tantalum, aluminum, metal carbides (e.g., hafnium carbide, zirconium carbide, titanium carbide, aluminum carbide), aluminides, ruthenium, palladium, platinum, cobalt, nickel, conductive metal oxides, or a combinations thereof. The thickness and/or the compositions of the work function layer may be fine-tuned to adjust the work function level.

The work function layer may be deposited over the gate dielectric layer 150 using an ALD process, a CVD process, a PVD process, an electroplating process, an electroless plating process, one or more other applicable processes, or a combination thereof. In some embodiments, the formation of the work function layer involves one or more patterning processes. As a result, the n-type work function layer and the p-type work function layer are selectively formed over different regions.

In some embodiments, a barrier layer is formed before the work function layer to interface the gate dielectric layer 150 with the subsequently formed work function layer. The barrier layer may also be used to prevent diffusion between the gate dielectric layer 150 and the subsequently formed work function layer. The barrier layer may be made of or include a metal-containing material. The metal-containing material may include titanium nitride, tantalum nitride, one or more other suitable materials, or a combination thereof. The barrier layer may be deposited using an ALD process, a CVD process, a PVD process, an electroplating process, an electroless plating process, one or more other applicable processes, or a combination thereof.

In some embodiments, the conductive fillings of the metal gate electrodes 152N and 152P are made of or include a metal material. The metal material may include tungsten, aluminum, copper, cobalt, one or more other suitable materials, or a combination thereof. A conductive layer used for forming the conductive filling may be deposited over the work function layer using a CVD process, an ALD process, a PVD process, an electroplating process, an electroless plating process, a spin coating process, one or more other applicable processes, or a combination thereof.

In some embodiments, a blocking layer is formed over the work function layer before the formation of the conductive layer used for forming the conductive filling. The blocking layer may be used to prevent the subsequently formed conductive layer from diffusing or penetrating into the work function layer. The blocking layer may be made of or include tantalum nitride, titanium nitride, one or more other suitable materials, or a combination thereof. The blocking layer may be deposited using an ALD process, a PVD process, an electroplating process, an electroless plating process, one or more other applicable processes, or a combination thereof.

Afterwards, a planarization process is performed to remove the portions of the metal gate stack layers outside of the trenches 142, in accordance with some embodiments. As a result, the remaining portions of the metal gate stack layers form the metal gate stacks 156A and 156B, as shown in FIG. 30.

In some embodiments, the conductive filling does not extend into the recesses 144 since the recesses 144 are small and have been filled with other elements such as the gate dielectric layer 150 and the work function layer. However, embodiments of the disclosure are not limited thereto. In some other embodiments, a portion of the conductive filling extends into the recesses 144.

In some embodiments, the crystallized semiconductor layer 208′ next to the epitaxial structure 138N and the crystallized semiconductor layer 208′ next to the epitaxial structure 138P are made of the same material. In some embodiments, the crystallized semiconductor layers 208′ are made of silicon. The epitaxial structure 138N may be made of phosphor-doped silicon, while the epitaxial structure 138N may be made of boron-doped silicon germanium.

However, embodiments of the disclosure are not limited thereto. Many variations and/or modifications can be made to embodiments of the disclosure. In some other embodiments, the crystallized semiconductor layers are made of a semiconductor material other than silicon.

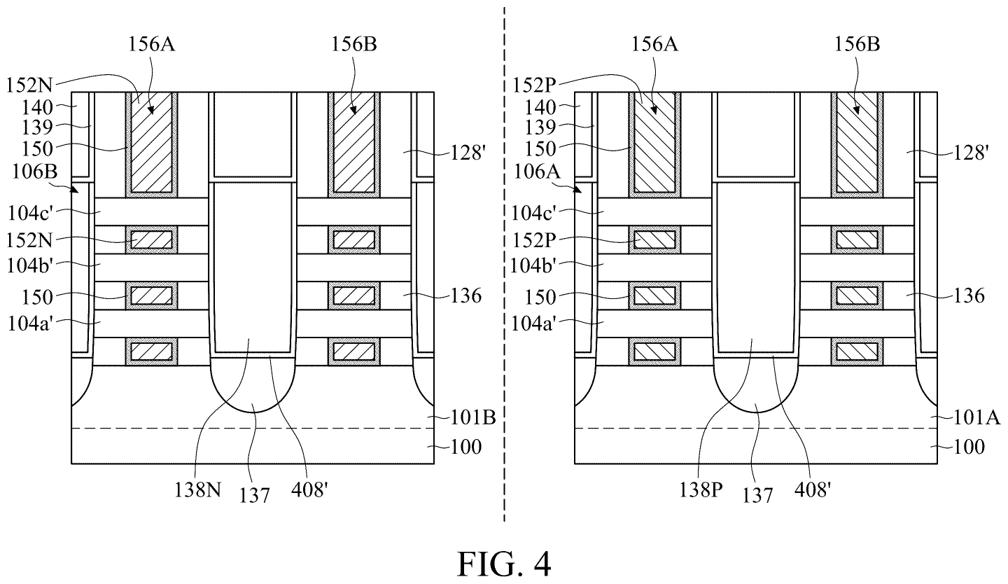

FIG. 4 is a cross-sectional view of an intermediate stage of a process for forming portions of a semiconductor device structure, in accordance with some embodiments. Similar to the embodiments shown in FIGS. 3A-30, a crystallized semiconductor layer 408′ is formed along the side edges of the semiconductor nanostructures 104a′-104c′ and the inner spacers 136 before the formation of the epitaxial structures 138N and 138P. In some embodiments, the crystallized semiconductor layer 408′ is made of silicon germanium.

Embodiments of the disclosure are not limited thereto. Many variations and/or modifications can be made to embodiments of the disclosure. In some embodiments, the crystallized semiconductor layer next to the epitaxial structure 138N and the crystallized semiconductor layer next to the epitaxial structure 138P are made of different materials.

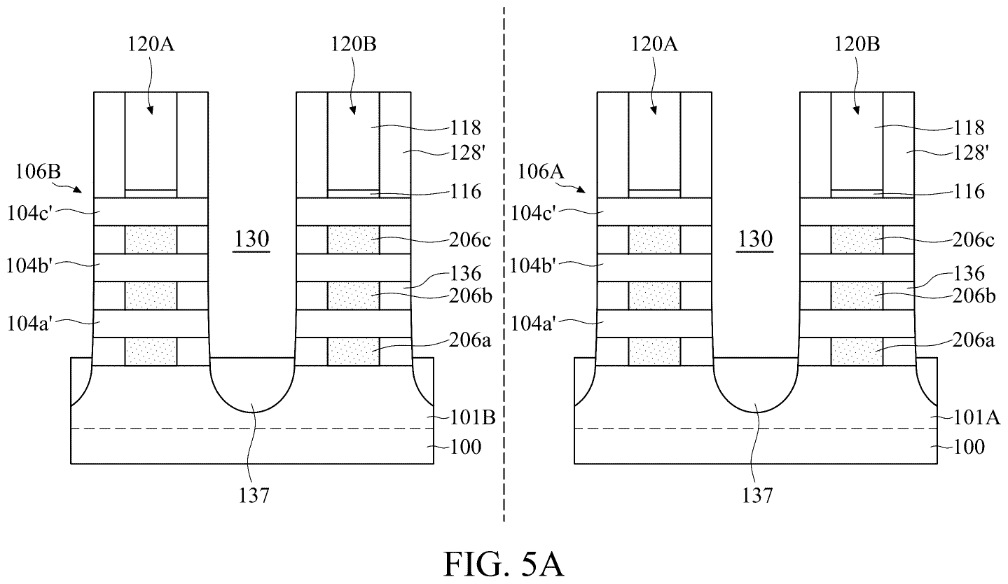

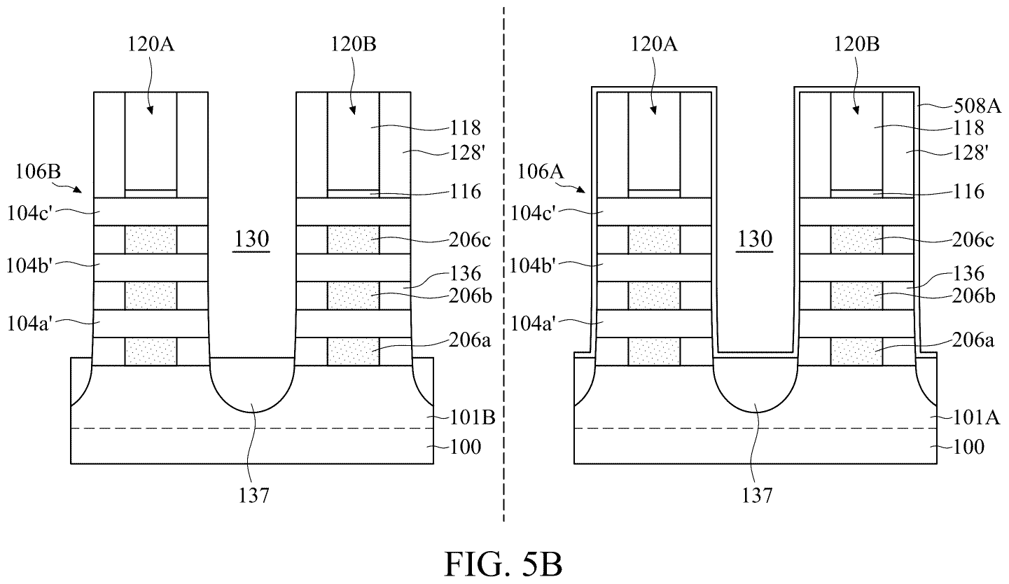

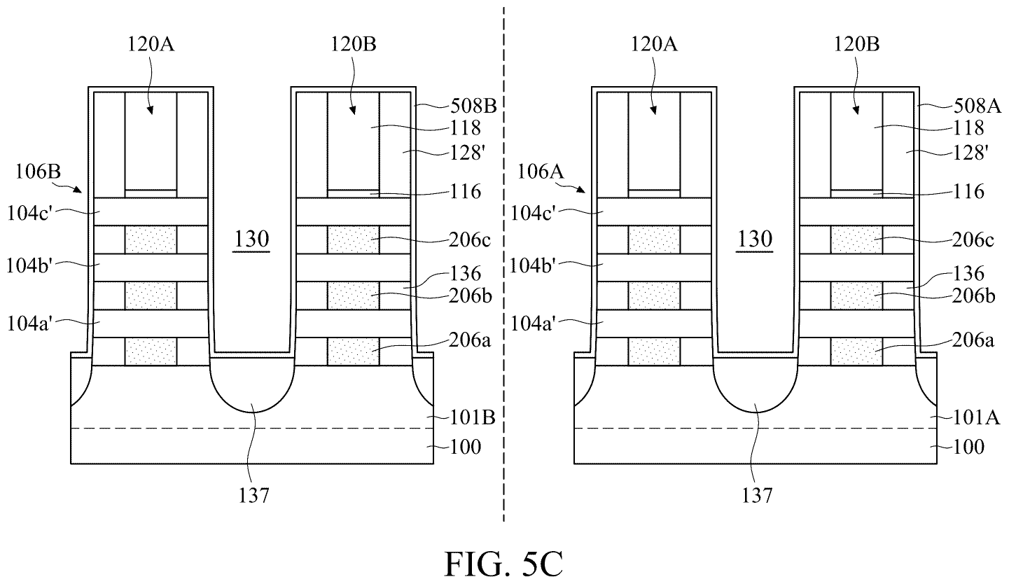

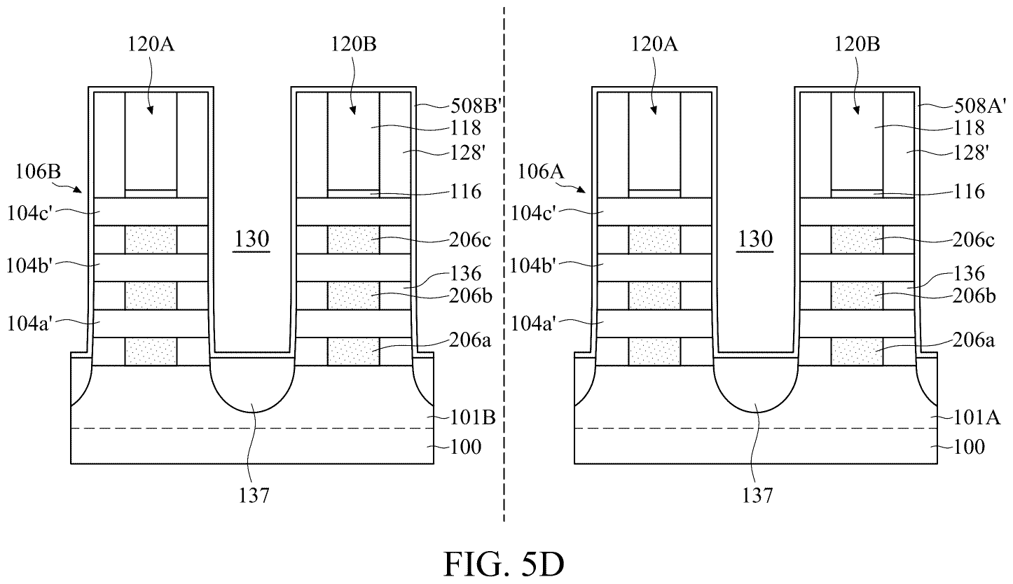

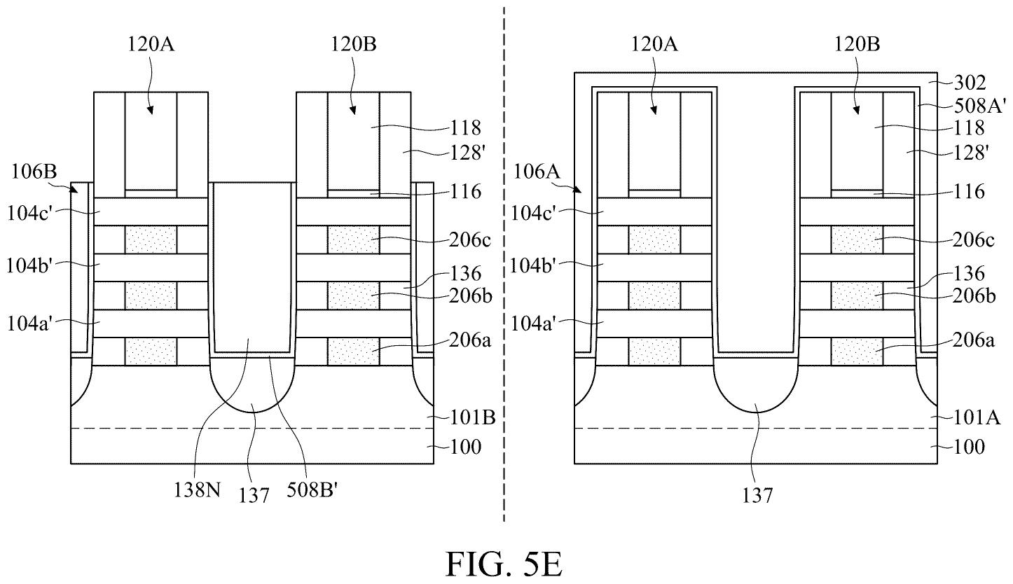

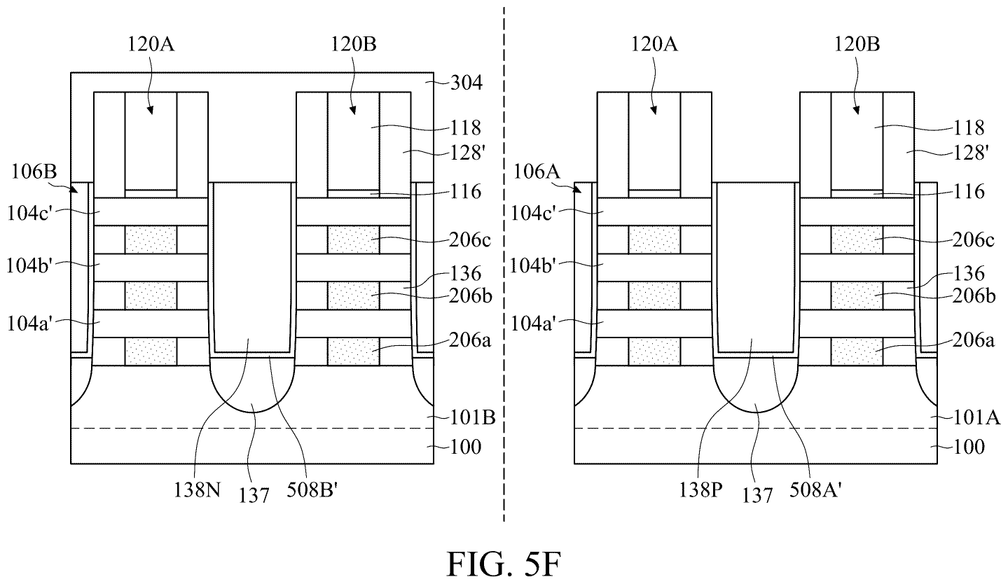

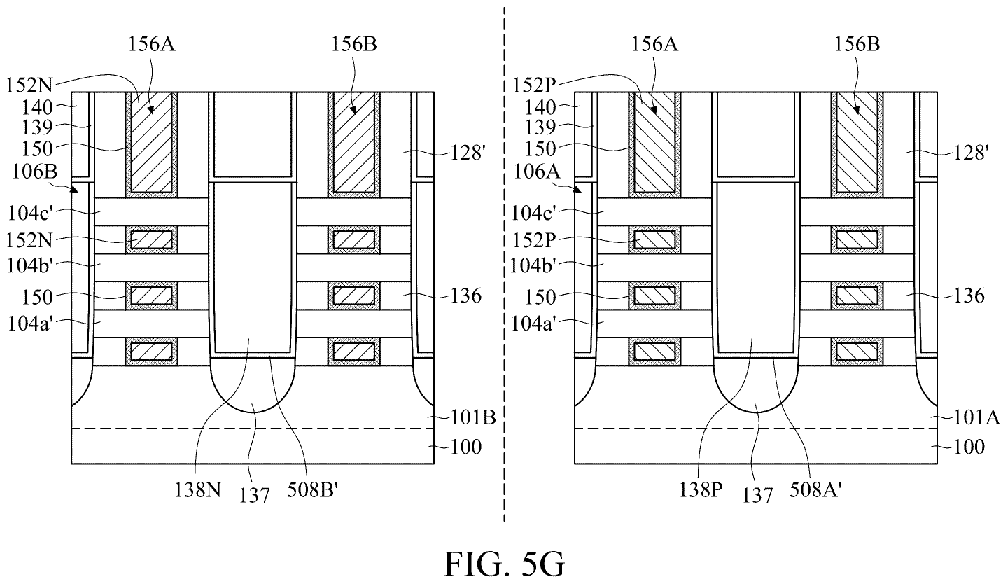

FIGS. 5A-5G are cross-sectional views of various stages of a process for forming portions of a semiconductor device structure, in accordance with some embodiments. As shown in FIG. 5A, a structure that is the same as or similar to that shown in FIG. 3G.

As shown in FIG. 5B, a patterned continuous semiconductor layer 508A is formed over the fin structure 106A, in accordance with some embodiments. In some embodiments, a continuous semiconductor layer that is similar to the continuous semiconductor layer 208 shown in FIG. 3H is formed. Afterwards, one or more photolithography processes and one or more etching processes are used to partially remove the continuous semiconductor layer. As a result, the remaining portion of the continuous semiconductor layer forms the patterned continuous semiconductor layer 508A, as shown in FIG. 5B. In some embodiments, the patterned continuous semiconductor layer 508A is an amorphous semiconductor layer that is made of silicon germanium.

As shown in FIG. 5C, a patterned continuous semiconductor layer 508B is formed over the fin structure 106B, in accordance with some embodiments. In some embodiments, a continuous semiconductor layer that is similar to the continuous semiconductor layer 208 shown in FIG. 3H is formed. Afterwards, one or more photolithography processes and one or more etching processes are used to partially remove the continuous semiconductor layer. As a result, the remaining portion of the continuous semiconductor layer forms the patterned continuous semiconductor layer 508B, as shown in FIG. 5C. In some embodiments, the patterned continuous semiconductor layer 508B is an amorphous semiconductor layer that is made of a semiconductor material other than that of the patterned continuous semiconductor layer 508B. In some embodiments, the patterned continuous semiconductor layer 508B is made of silicon.

As shown in FIG. 5D, similar to the embodiments illustrated in FIG. 3I, the patterned continuous semiconductor layers 508A and 508B are crystallized to respectively form crystallized semiconductor layers 508A′ and 508B′, in accordance with some embodiments. In some embodiments, the crystallized semiconductor layers 508A′ and 508B′ are single crystalline. In some embodiments, the crystallized semiconductor layer 508A′ is made of silicon germanium, and the crystallized semiconductor layer 508B′ is made of silicon.

As shown in FIG. 5E, similar to the embodiments illustrated in FIG. 3J, a mask element 302 is formed, in accordance with some embodiments. Afterwards, epitaxial structures 138N are formed. The material and formation method of the epitaxial structures 138N may be the same as or similar to those of the epitaxial structures 138N shown in FIG. 3J.

Afterwards, the mask element 302 is removed. As shown in FIG. 5F, similar to the embodiments illustrated in FIG. 3K, a mask element 304 is formed, in accordance with some embodiments. Afterwards, epitaxial structures 138P are formed. The material and formation method of the epitaxial structures 138P may be the same as or similar to those of the epitaxial structures 138P shown in FIG. 3K.

Afterwards, the processes that are the same as or similar to those shown in FIGS. 3L-3O are performed. As a result, the structure shown in FIG. 5G is formed, in accordance with some embodiments.

In some embodiments, multiple dielectric nanostructures 206a-206c are formed to replace the semiconductor layers 102a-102c. However, embodiments of the disclosure are not limited thereto. Many variations and/or modifications can be made to embodiments of the disclosure. In some other embodiments, the semiconductor layers 102a-102c are not replaced with dielectric nanostructures.

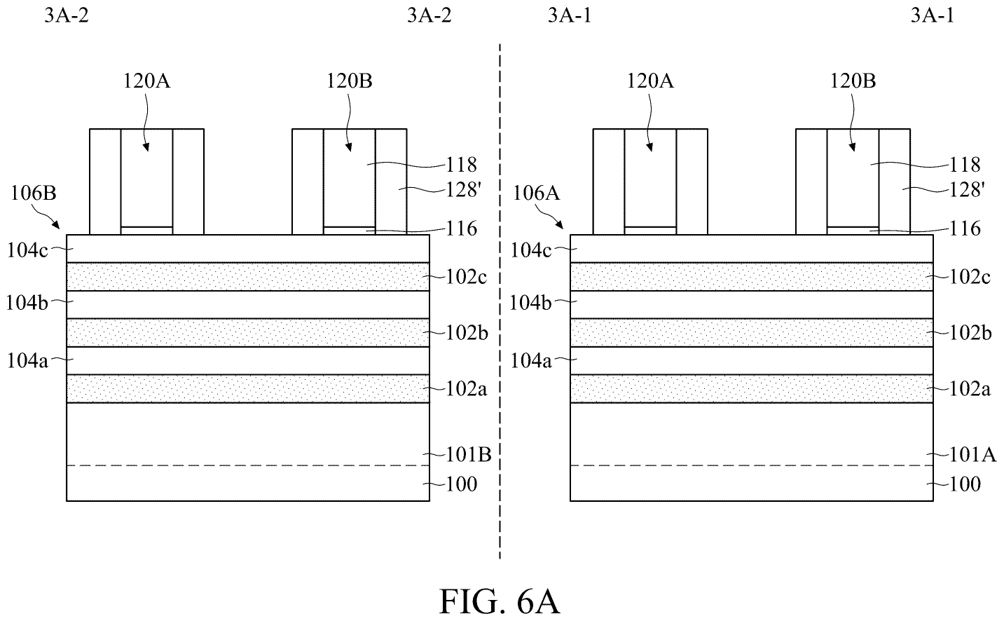

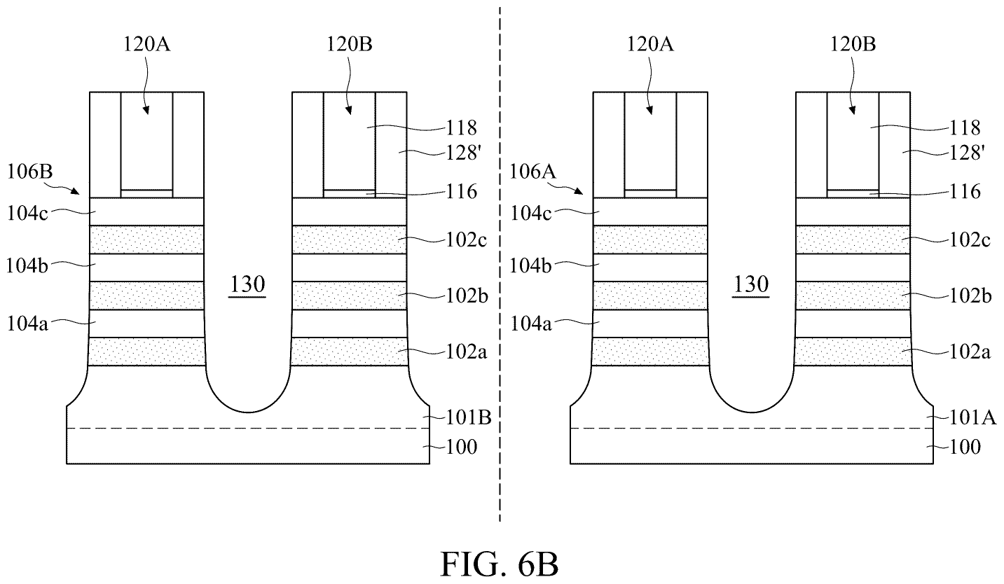

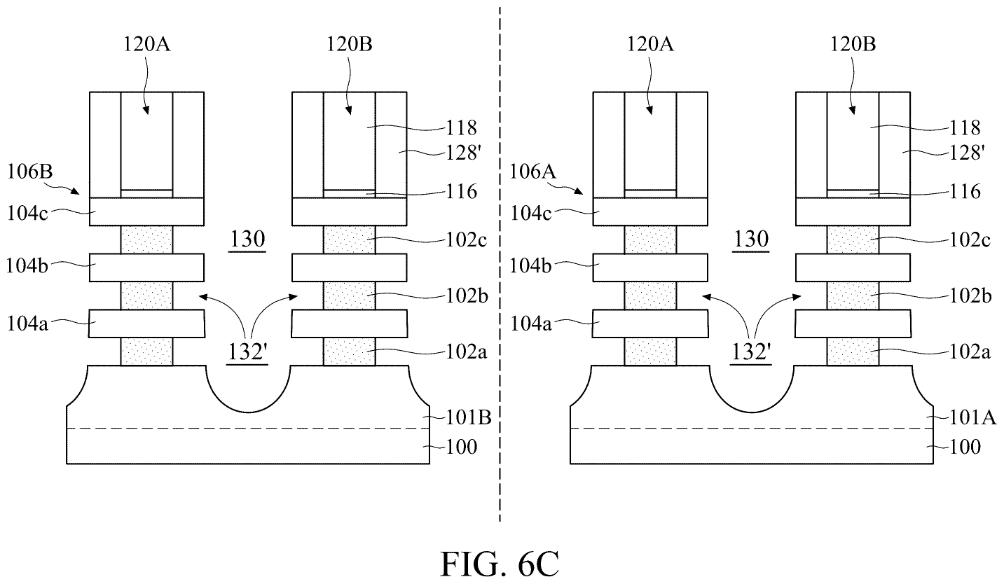

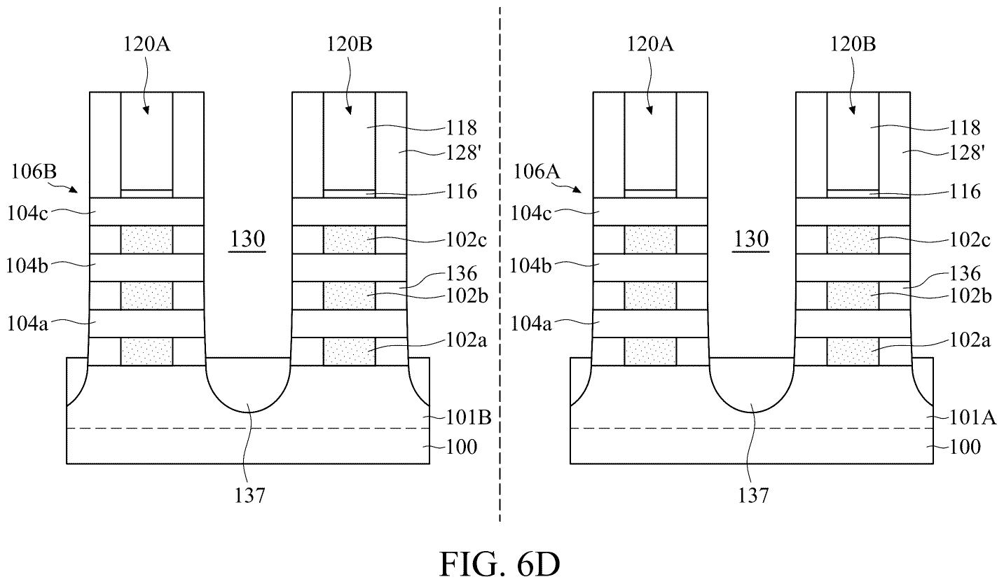

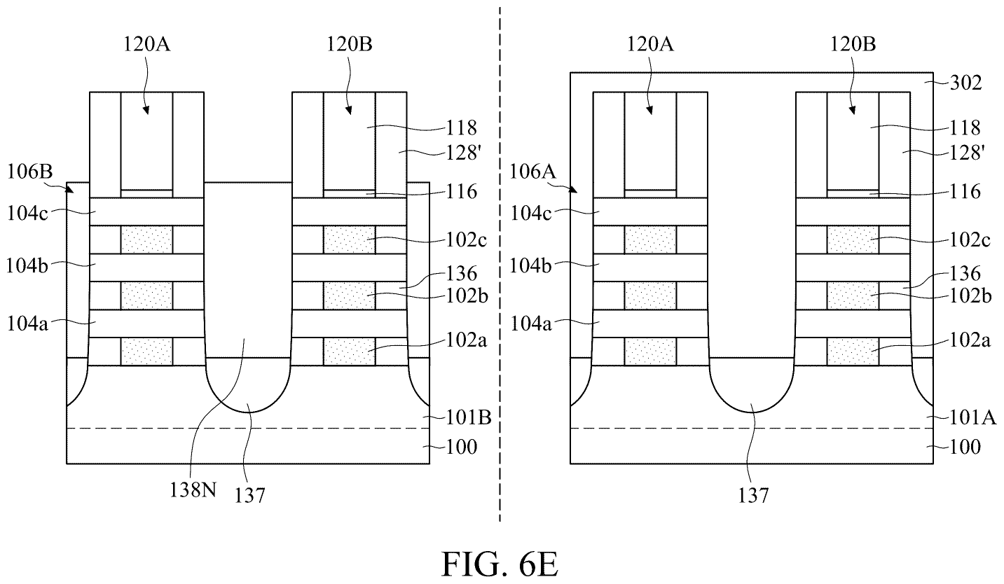

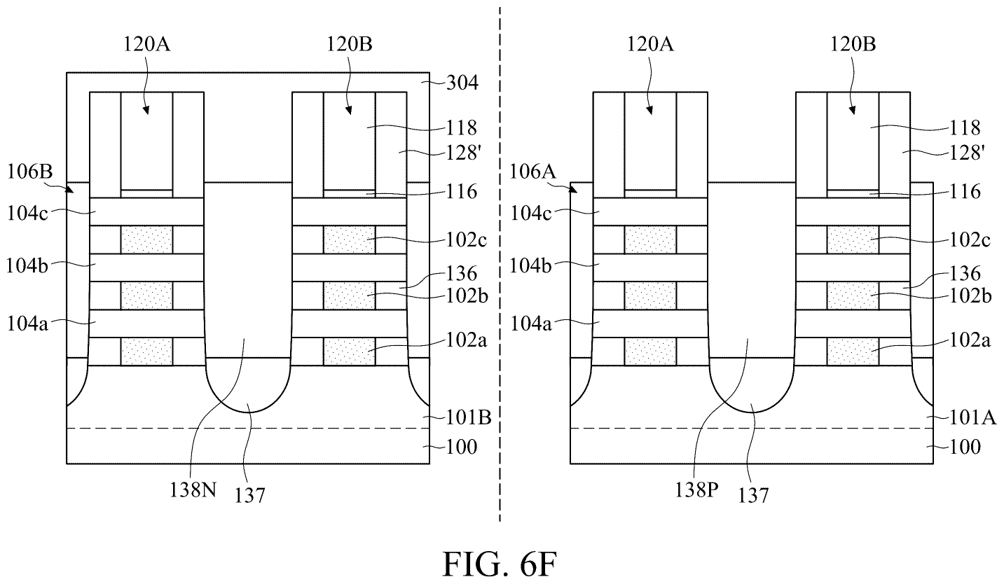

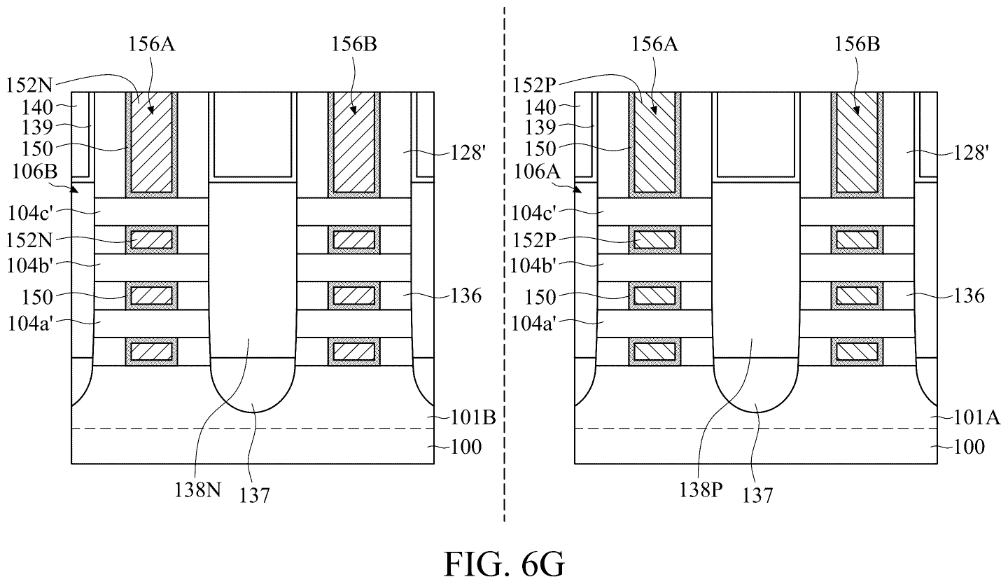

FIGS. 6A-6G are cross-sectional views of various stages of a process for forming portions of a semiconductor device structure, in accordance with some embodiments. As shown in FIG. 6A, a structure that is the same as or similar to that shown in FIG. 3A is formed. Afterwards, similar to the embodiments illustrated in FIG. 3B, the fin structures 106A and 106B are partially removed to form multiple recesses 130, as shown in FIG. 6B in accordance with some embodiments.

As shown in FIG. 6C, similar to the embodiments illustrated in FIG. 3E, the semiconductor layers 102a-102c are laterally etched to form multiple recesses 132′, in accordance with some embodiments.

Afterwards, similar to the embodiments illustrated in FIGS. 3F and 3G, inner spacers 136 and semiconductor isolation structures 137 are formed, as shown in FIG. 6D in accordance with some embodiments.

As shown in FIG. 6E, similar to the embodiments illustrated in FIG. 3J, a mask element 302 is formed to cover the fin structure 106A and portions of the dummy gate stacks 120A and 120B nearby, in accordance with some embodiments. Afterwards, similar to the embodiments illustrated in FIG. 3J, epitaxial structures 138N are formed, as shown in FIG. 6E.

In some embodiments, unlike the embodiments shown in FIG. 3J, no crystallized semiconductor layer is formed before the formation of the epitaxial structures 138N. As mentioned above, in some embodiments, the formation of the crystallized semiconductor layer involves a thermal process. The thermal process may cause germanium to diffuse from the semiconductor layers 102a-102c into the adjacent semiconductor layers 104a-104c, which may adversely affect the quality and reliability of the semiconductor layers 102c. Therefore, in some embodiments, no crystallized semiconductor layer is formed before the formation of the epitaxial structures 138N, as shown in FIG. 6E.

In some embodiments, the epitaxial structures 138N are directly grown on the dielectric surfaces of the inner spacers 136. However, the presence of the inner spacers 136 may result in poor crystal quality of the epitaxial structures 138N. Defects such as dislocation defects may be formed in the epitaxial structures 138N. In some embodiments, the epitaxial structures 138N of the embodiments shown in FIG. 3J have superior crystallinity compared to the epitaxial structures 138N of the embodiments shown in FIG. 6E. The epitaxial structures 138N of the embodiments shown in FIG. 3J may have less defects.

Afterwards, the mask element 302 is removed. As shown in FIG. 6F, similar to the embodiments illustrated in FIG. 3K, a mask element 304 is formed to cover the fin structure 106B and portions of the dummy gate stacks 120A and 120B nearby, in accordance with some embodiments. Afterwards, similar to the embodiments illustrated in FIG. 3K, epitaxial structures 138P are formed, as shown in FIG. 6F.

In some embodiments, unlike the embodiments shown in FIG. 3K, no crystallized semiconductor layer is formed before the formation of the epitaxial structures 138P. As mentioned above, in some embodiments, the formation of the crystallized semiconductor layer involves a thermal process. The thermal process may cause germanium to diffuse from the semiconductor layers 102a-102c into the adjacent semiconductor layers 104a-104c, which may adversely affect the quality and reliability of the semiconductor layers 102c. Therefore, in some embodiments, no crystallized semiconductor layer is formed before the formation of the epitaxial structures 138P, as shown in FIG. 6F.

In some embodiments, the epitaxial structures 138P are directly grown on the dielectric surfaces of the inner spacers 136. However, the presence of the inner spacers 136 may result in poor crystal quality of the epitaxial structures 138P. Defects such as dislocation defects may be formed in the epitaxial structures 138P. In some embodiments, the epitaxial structures 138P of the embodiments shown in FIG. 3K have superior crystallinity compared to the epitaxial structures 138N of the embodiments shown in FIG. 6F.

Afterwards, the processes that are the same as or similar to those shown in FIGS. 3L-3O are performed. As a result, the structure shown in FIG. 6G is formed, in accordance with some embodiments.

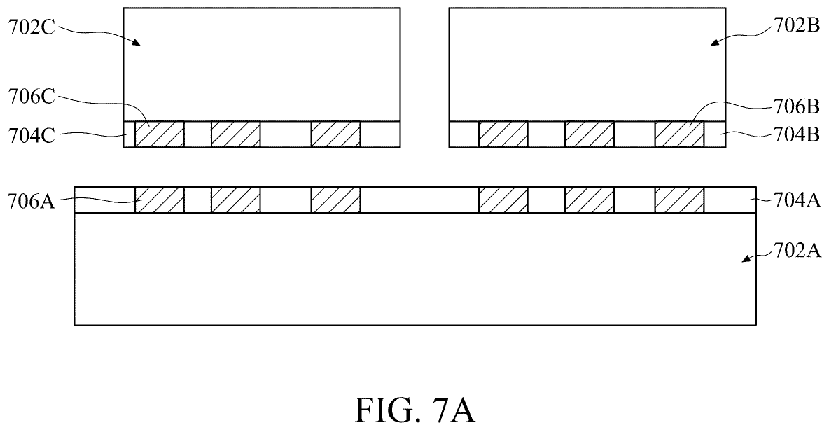

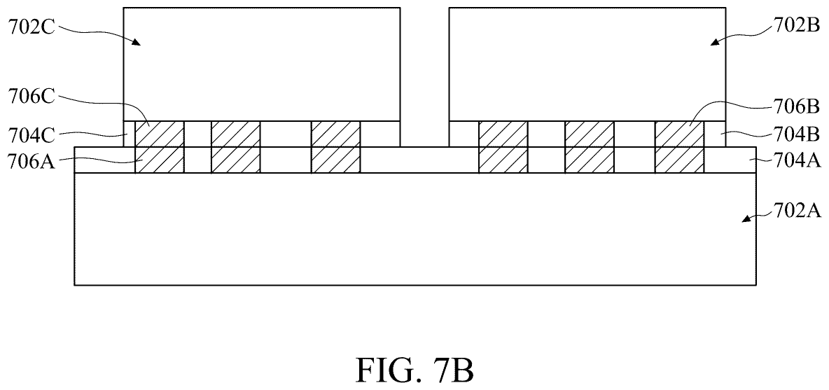

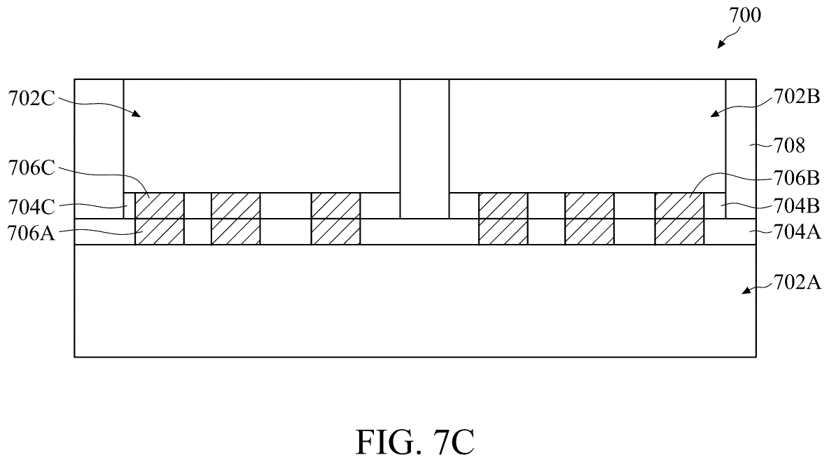

Many variations and/or modifications can be made to embodiments of the disclosure. FIGS. 7A-7C are cross-sectional views of various stages of a process for forming portions of a semiconductor device structure, in accordance with some embodiments. As shown in FIG. 7A, multiple chip-containing structures 702A, 702B, and 702C are formed or received. In some embodiments, the chip-containing structures 702A, 702B, and 702C are semiconductor chips that will be integrated together. In some embodiments, the transistor devices in one or more of the chip-containing structures 702A, 702B, and 702C are formed using the processes illustrated in FIGS. 3A-30, 4, and/or 5A-5G. In some embodiments, the transistor devices in one or more of the chip-containing structures 702A, 702B, and 702C are formed using the processes illustrated in FIGS. 6A-6G.

In some embodiments, the chip-containing structures 702A, 702B, and 702C include dielectric bonding structures 704A, 704B, and 704C and metal bonding structures 706A, 706B, and 706C. The formation of the dielectric bonding structures 704A-704C and the metal bonding structures 706A-706C involve planarization processes such as chemical mechanical polishing (CMP) processes. The planarization processes provide the chip-containing structures 702A, 702B, and 702C with highly planarized bonding surfaces.

As shown in FIG. 7B, the chip-containing structure 702A-702C are bonded together through direct bonding, in accordance with some embodiments. The direct bonding may be a bonding that includes metal-to-metal bonding and dielectric-to-dielectric bonding. For example, the dielectric bonding structures 704A and 704B are in direct contact with each other and together form the dielectric-to-dielectric bonding. Similarly, the dielectric bonding structures 704A and 704C are in direct contact with each other and together form the dielectric-to-dielectric bonding. The metal bonding structures 706A and 706B are in direct contact with each other and together form the metal-to-metal bonding. Similarly, the metal bonding structures 706A and 706Cs are in direct contact with each other and together form the metal-to-metal bonding. In some embodiments, there is no tin-containing solder elements formed between the chip-containing structures 706A and 706B or between the chip-containing structures 706A and 706C.

In some embodiments, the chip-containing structures 702B and 702C are placed directly on the dielectric bonding structure 704A and the metal bonding structures 706A of the chip-containing structures 702A. As a result, these chip-containing structures 702A-702C are bonded together.

As mentioned above, before the placing of the chip-containing structure 30, planarization processes are performed, so as to provide highly planarized bonding surfaces. In some embodiments, a thermal operation is then used to enhance the bonding between the metal bonding structures 706A-706C. The temperature of the thermal operation may within a range from about 100 degrees C. to about 500 degrees C. In some embodiments, there is no tin-containing solder element formed between the chip-containing structures 702A and 702B or between the chip-containing structures 702A and 702C.

As shown in FIG. 7C, a protective layer 708 is then formed to laterally surround the chip-containing structures 702B and 702C, in accordance with some embodiments. The protective layer 708 may be made of or include silicon oxide, silicon oxynitride, carbon-containing silicon oxide, epoxy-based molding material, another suitable material, or a combination thereof.

In some embodiments, the transistor devices in the chip-containing structure 702A are formed using the process illustrated in FIGS. 6A-6G, and the transistor devices in the chip-containing structure 702B are formed using the process illustrated in FIGS. 3A-3O, 4, or 5A-5G. In some embodiments, the epitaxial structures 138N and/or 138P in the chip-containing structure 702B has superior crystallinity compared to the epitaxial structures 138N and/or 138P in the chip-containing structure 702A.

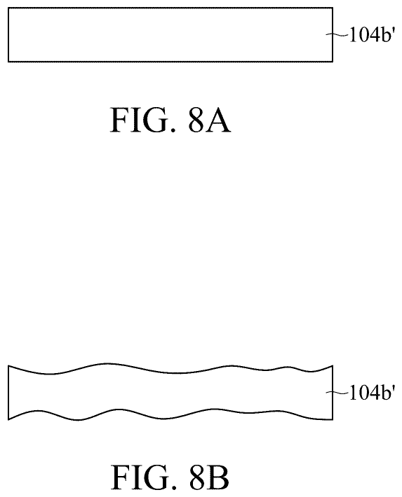

FIG. 8A is a cross-sectional view of a portion of a semiconductor device structure, in accordance with some embodiments. FIG. 8B is a cross-sectional view of a portion of a semiconductor device structure, in accordance with some embodiments. In some embodiments, FIG. 8A shows one of the semiconductor nanostructures 104b′ formed in the chip-containing structure 702B in FIG. 7C, and FIG. 8B shows one of the semiconductor nanostructures 104b′ formed in the chip-containing structure 702A in FIG. 7C.

As mentioned above, in some embodiments, the formation of the chip-containing structure 702B involves the processes illustrated in FIGS. 3A-30, 4, or 5A-5G, in which dielectric nanostructures 206a-206c are formed to replace the semiconductor layers 102a-102c that contain germanium. Therefore, germanium is prevented from diffusing into the semiconductor nanostructures 104a′-104c′ during the subsequent thermal processes. The semiconductor nanostructures 104a′-104c′ may thus have smooth profile. As shown in FIG. 8A, one of the semiconductor nanostructures 104b′ is shown. The semiconductor nanostructures 104b′ has a smooth top surface and a smooth bottom surface, resulting in low electrical resistance.

As mentioned above, in some embodiments, the formation of the chip-containing structure 702A involves the processes illustrated in FIGS. 6A-6G, in which no dielectric nanostructures 206a-206c are formed to replace the semiconductor layers 102a-102c that contain germanium. Therefore, germanium may diffuse into the semiconductor nanostructures 104a′-104c′ during subsequent thermal processes, leading to a rough surface condition of the semiconductor nanostructures 104a′-104c′. As shown in FIG. 8B, one of the semiconductor nanostructures 104b′ is shown. The semiconductor nanostructures 104b′ has a rough top surface and a rough bottom surface.

Many variations and/or modifications can be made to embodiments of the disclosure. In some embodiments, there are three channel structures (such as the semiconductor nanostructures 104a′-104c′) formed between the nearby epitaxial structures 138P or 138N. However, embodiments of the disclosure are not limited thereto. Many variations and/or modifications can be made to embodiments of the disclosure. In some embodiments, the total number of semiconductor nanostructures between the nearby epitaxial structures 138P or 138N is greater than three. In some other embodiments, the total number of semiconductor nanostructures between the nearby epitaxial structures 138P or 138N is smaller than three. The total number of semiconductor nanostructures (or channel structures) between the nearby epitaxial structures 138P or 138N may be fine-tuned to meet requirements. For example, the total number of semiconductor nanostructures between the nearby epitaxial structures 138P or 138N may be between 2 and 10. The semiconductor nanostructures may have many applicable profiles. The semiconductor nanostructures may include nanosheets, nanowires, or other suitable nanostructures.

Embodiments of the disclosure form a semiconductor device structure with a crystallized semiconductor layer formed between the epitaxial structure and the inner spacers. The epitaxial structure is thus grown on the semiconductor surface of the crystallized semiconductor layer rather than directly on the dielectric surfaces of the inner spacers. As a result, the epitaxial structure exhibits good crystal quality due to its growth on the crystallized semiconductor layer. As a result, the epitaxial structure may exhibit high crystallinity, which leads to low resistance and high strain. The quality and reliability of the semiconductor device structure are greatly improved.

In accordance with some embodiments, a method for forming a semiconductor device structure is provided. The method includes forming multiple semiconductor nanostructures and multiple dielectric nanostructures over a substrate. The semiconductor nanostructures and the dielectric nanostructures are laid out in an alternating manner. The method also includes forming inner spacers over edges of the dielectric nanostructures and forming a continuous semiconductor layer along edges of the semiconductor nanostructures and the inner spacers. The method further includes annealing the continuous semiconductor layer to form a crystallized semiconductor layer and growing an epitaxial structure on the crystallized semiconductor layer.

In accordance with some embodiments, a method for forming a semiconductor device structure is provided. The method includes forming multiple semiconductor nanostructures and multiple dielectric nanostructures over a substrate. The semiconductor nanostructures and the dielectric nanostructures are laid out in an alternating manner. The method also includes forming an amorphous semiconductor layer covering edges of the semiconductor nanostructures and the dielectric nanostructures. The method further includes crystallizing the amorphous semiconductor layer to form a crystallized semiconductor layer and forming an epitaxial structure on the crystallized semiconductor layer.

In accordance with some embodiments, a semiconductor device structure is provided. The semiconductor device structure includes multiple semiconductor nanostructures and a gate stack over the semiconductor nanostructures. The semiconductor device structure also includes a first epitaxial structure and a second epitaxial structure. The semiconductor nanostructures are sandwiched between the first epitaxial structure and the second epitaxial structure. The semiconductor device structure further includes a continuous semiconductor layer between the first epitaxial structure and the semiconductor nanostructures. The continuous semiconductor layer continuously extends along edges of the semiconductor nanostructures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a plurality of semiconductor nanostructures and a plurality of dielectric nanostructures over a substrate, wherein the semiconductor nanostructures and the dielectric nanostructures are laid out in an alternating manner;
forming inner spacers over edges of the dielectric nanostructures;
forming a continuous semiconductor layer along edges of the semiconductor nanostructures and the inner spacers;
annealing the continuous semiconductor layer to form a crystallized semiconductor layer; and
growing an epitaxial structure on the crystallized semiconductor layer.

2. The method for forming a semiconductor device structure as claimed in claim 1, wherein the annealing of the continuous semiconductor layer is performed using a laser annealing process.

3. The method for forming a semiconductor device structure as claimed in claim 1, wherein the annealing of the continuous semiconductor layer is performed using an ultra sub-second annealing process.

4. The method for forming a semiconductor device structure as claimed in claim 1, further comprising:
laterally etching the dielectric nanostructures to form a plurality of recesses; and
forming the inner spacers in the recesses.

5. The method for forming a semiconductor device structure as claimed in claim 1, further comprising:
forming a plurality of second semiconductor nanostructures and a plurality of second dielectric nanostructures over a substrate, wherein the second semiconductor nanostructures and the second dielectric nanostructures are laid out in an alternating manner;
forming second inner spacers over edges of the second dielectric nanostructures;
forming a second continuous semiconductor layer along edges of the second semiconductor nanostructures and the second inner spacers;
annealing the second continuous semiconductor layer to form a second crystallized semiconductor layer; and
growing a second epitaxial structure on the second crystallized semiconductor layer, wherein the second epitaxial structure and the epitaxial structure have opposite conductivity types.

6. The method for forming a semiconductor device structure as claimed in claim 5, wherein the continuous semiconductor layer and the second continuous semiconductor layer are formed sequentially, and the continuous semiconductor layer and the second continuous semiconductor layer are made of different materials.

7. A method for forming a semiconductor device structure, comprising:
forming a plurality of semiconductor nanostructures and a plurality of dielectric nanostructures over a substrate, wherein the semiconductor nanostructures and the dielectric nanostructures are laid out in an alternating manner;
forming an amorphous semiconductor layer covering edges of the semiconductor nanostructures and the dielectric nanostructures;
crystallizing the amorphous semiconductor layer to form a crystallized semiconductor layer; and
forming an epitaxial structure on the crystallized semiconductor layer.

8. The method for forming a semiconductor device structure as claimed in claim 7, further comprising irradiating the amorphous semiconductor layer with a laser beam to convert the amorphous semiconductor layer into the crystallized semiconductor layer.

9. The method for forming a semiconductor device structure as claimed in claim 7, further comprising thermally annealing the amorphous semiconductor layer to convert the amorphous semiconductor layer into the crystallized semiconductor layer.

10. The method for forming a semiconductor device structure as claimed in claim 7, further comprising:
laterally etching the dielectric nanostructures to form a plurality of recesses; and
forming inner spacers in the recesses before the amorphous semiconductor layer is formed, wherein the inner spacers are in direct contact with the amorphous semiconductor layer after the amorphous semiconductor layer is formed.

11. A semiconductor device structure, comprising:
a plurality of semiconductor nanostructures;
a gate stack over the semiconductor nanostructures;
a first epitaxial structure and a second epitaxial structure, wherein the semiconductor nanostructures are sandwiched between the first epitaxial structure and the second epitaxial structure; and
a continuous semiconductor layer between the first epitaxial structure and the semiconductor nanostructures, wherein the continuous semiconductor layer continuously extends along edges of the semiconductor nanostructures.

12. The semiconductor device structure as claimed in claim 11, wherein the continuous semiconductor layer is single crystalline.

13. The semiconductor device structure as claimed in claim 11, wherein the first epitaxial structure comprises p-type doped silicon germanium, and the continuous semiconductor layer comprises silicon.

14. The semiconductor device structure as claimed in claim 11, wherein the first epitaxial structure comprises n-type doped silicon, and the continuous semiconductor layer comprises silicon.

15. The semiconductor device structure as claimed in claim 11, wherein the first epitaxial structure comprises p-type doped silicon germanium, and the continuous semiconductor layer comprises silicon germanium.

16. The semiconductor device structure as claimed in claim 11, further comprising:
a plurality of second semiconductor nanostructures;
a third epitaxial structure and a fourth epitaxial structure, wherein the second semiconductor nanostructures are sandwiched between the third epitaxial structure and the fourth epitaxial structure; and
a second continuous semiconductor layer between the third epitaxial structure and the second semiconductor nanostructures, wherein the second continuous semiconductor layer continuously extends along edges of the second semiconductor nanostructures.

17. The semiconductor device structure as claimed in claim 16, wherein:
the first epitaxial structure comprises p-type doped silicon germanium,
the continuous semiconductor layer comprises silicon germanium,
the third epitaxial structure comprises n-type doped silicon, and
the second continuous semiconductor layer comprises silicon.

18. The semiconductor device structure as claimed in claim 11, further comprising:
a plurality of second semiconductor nanostructures; and
a third epitaxial structure and a fourth epitaxial structure, wherein the second semiconductor nanostructures are sandwiched between the third epitaxial structure and the fourth epitaxial structure, and the second semiconductor nanostructures are in direct contact with the third epitaxial structure and the fourth epitaxial structure.

19. The semiconductor device structure as claimed in claim 18, further comprising:
a first chip-containing structure, wherein the semiconductor nanostructures and the first epitaxial structure are within the first chip-containing structure; and
a second chip-containing structure bonded to the first chip-containing structure through dielectric-to-dielectric bonding and metal-to-metal bonding, wherein the second semiconductor nanostructures and the third epitaxial structure are within the second chip-containing structure.

20. The semiconductor device structure as claimed in claim 19, further comprising:
a first inner spacer between two of the semiconductor nanostructures, wherein the continuous semiconductor layer is between the first inner spacer and the first epitaxial structure; and
a second inner spacer between two of the second semiconductor nanostructures, wherein the second inner spacer is in direct contact with the third epitaxial structure.
